(19) United States
(12) Patent Application Publication
(10) Pub. No.: US 2024/0332345 A1
(43) Pub. Date: Oct. 3, 2024

(54) INSULATING CHIP AND SIGNAL PROPAGATING DEVICE

(71) Applicant: ROHM CO., LTD., Kyoto-shi (JP)

(72) Inventor: Bungo TANAKA, Kyoto-shi (JP)

(73) Assignee: ROHM CO., LTD., Kyoto-shi (JP)

(21) Appl. No.: 18/676,517

(22) Filed: May 29, 2024

Related U.S. Application Data
(63) Continuation of application No. PCT/JP2022/043765, filed on Nov. 28, 2022.

(30) Foreign Application Priority Data
Dec. 1, 2021 (JP) 2021-195483

(51) Int. Cl. H01L 23/522; H01L 23/00; H01L 23/498; H01L 23/532; H01L 23/58

(52) U.S. Cl. CPC H01L 28/60; H01L 23/49811; H01L 23/5223; H01L 23/53295; H01L 23/585; H01L 24/32; H01L 24/48; H01L 2224/32225; H01L 2224/48137; H01L 2224/48195; H01L 2924/19041

(57) ABSTRACT

An insulating chip includes a substrate; an element insulating layer which is disposed on the substrate, and a capacitor which is embedded in the element insulating layer and which includes a first electrode plate and a second electrode plate. The first electrode plate and the second electrode plate are disposed face to face in a first direction that is orthogonal to the thickness direction of the element insulating layer. A signal propagating device includes the insulating chip.

### CROSS-REFERENCE TO RELATED APPLICATIONS

This application is a continuation of International Application No. PCT/JP2022/043765, filed Nov. 28, 2022, which claims priority to Japanese Patent Application No. 2021-195483, filed Dec. 1, 2021, the entire contents of each are incorporated herein by reference.

### BACKGROUND

The present disclosure relates to an insulating chip and a signal transmission device.

A known example of a signal transmission device is an insulated gate driver that applies a gate voltage to the gate of a switching element such as a transistor (for example, refer to JP 2020-25102 A).

### BRIEF DESCRIPTION OF DRAWINGS

FIG. 1 is a schematic circuit diagram showing a circuit configuration of a signal transmission device in an embodiment.

FIG. 2 is a schematic cross-sectional view showing a cross-sectional structure of the signal transmission device shown in FIG. 1.

FIG. 3 is a schematic plan view showing a planar structure of an insulating chip in the signal transmission device shown in FIG. 2.

FIG. 4 is a schematic cross-sectional view showing a cross-sectional structure of the insulating chip taken in line F4-F4 in FIG. 3.

FIG. 5 is a schematic cross-sectional view showing a cross-sectional structure of the insulating chip taken in line F5-F5 in FIG. 3.

FIG. 6 is a schematic cross-sectional view showing a cross-sectional structure of the insulating chip taken in line F6-F6 in FIG. 3.

FIG. 7 is a schematic cross-sectional view showing a cross-sectional structure of the insulating chip taken in line F7-F7 in FIG. 3.

FIG. 8 is a schematic cross-sectional view showing a cross-sectional structure of a signal transmission device in a modified example.

FIG. 9 is a schematic cross-sectional view showing a cross-sectional structure of an insulating chip in a modified example.

FIG. 10 is a schematic cross-sectional view showing a cross-sectional structure of an insulating chip in a modified example.

FIG. 11 is a schematic plan view showing a planar structure of an insulating chip in a modified example.

FIG. 12 is a schematic plan view showing a planar structure of an insulating chip in a modified example.

FIG. 13 is a schematic plan view showing a planar structure of an insulating chip in a modified example.

FIG. 14 is a schematic plan view showing a planar structure of an insulating chip in a modified example.

### DETAILED DESCRIPTION

Embodiments of an insulating chip and a signal transmission device according to the present disclosure will be described below with reference to the drawings. In the drawings, components may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### Embodiments

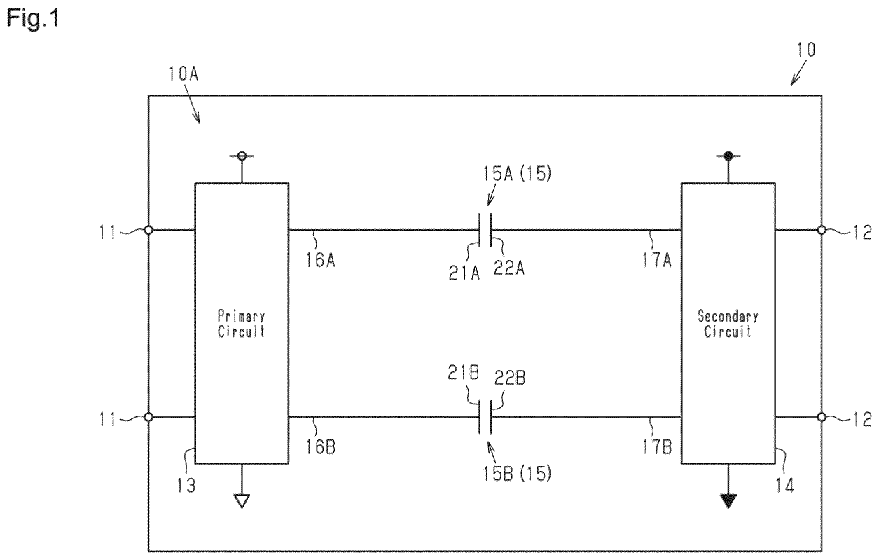

The structures of embodiments of an insulating chip and a signal transmission device will now be described with reference to FIGS. 1 to 7. FIG. 1 is a simplified diagram showing an example of a circuit configuration of a signal transmission device 10.

### Circuit Configuration of Signal Transmission Device

As shown in FIG. 1, the signal transmission device 10 transmits a pulse signal while electrically insulating primary terminals 11 from secondary terminals 12. The signal transmission device 10 is a digital isolator and is, for example, an AC/DC converter, a gate driver, or an electronic component included in the AC/DC converter or the gate driver. The signal transmission device 10 includes a signal transmission circuit 10A that includes a primary circuit 13 electrically connected to the primary terminals 11, a secondary circuit 14 electrically connected to the secondary terminals 12, and a capacitor 15 electrically connecting the primary circuit 13 and the secondary circuit 14. In the present embodiment, the primary circuit 13 corresponds to a “first circuit,” and the secondary circuit 14 corresponds to a “second circuit.”

The primary circuit 13 is configured to be actuated by application of a first voltage. In an example, the primary circuit 13 is electrically connected to an external controller (not shown).

The secondary circuit 14 is configured to be actuated by application of a second voltage that differs from the first voltage. In an example, the second voltage is higher than the first voltage. The first voltage and the second voltage are direct current voltages. In an example, the secondary circuit 14 is electrically connected to a drive circuit that is a subject controlled by the controller. An example of the drive circuit is a switching circuit.

The signal transmission device 10 is configured so that when the primary circuit 13 receives a control signal from the controller through the primary terminals 11, the signal is transmitted from the primary circuit 13 to the secondary circuit 14 through the capacitor 15, and the secondary circuit 14 outputs the signal to the drive circuit through the secondary terminals 12. The signal transmission device 10 is configured to transmit a signal from the primary circuit 13 toward the secondary circuit 14 through the capacitor 15.

In the signal transmission circuit 10A, the primary circuit 13 and the secondary circuit 14 are electrically insulated by the capacitor 15. More specifically, the capacitor 15 allows transmission of a pulse signal while restricting transmission of a direct current voltage between the primary circuit 13 and the secondary circuit 14.

That is, the state in which the primary circuit 13 and the secondary circuit 14 are insulated refers to a state in which transmission of a direct current voltage between the primary circuit 13 and the secondary circuit 14 is blocked, whereas transmission of a pulse signal from the primary circuit 13 to the secondary circuit 14 is allowed. Thus, the secondary circuit 14 is configured to receive a signal from the primary circuit 13.

The insulation voltage of the signal transmission device 10 is, for example, in a range of 2500 Vrms to 7500 Vrms. In the present embodiment, the insulation voltage of the signal transmission device 10 is approximately 5700 Vrms. However, the insulation voltage of the signal transmission device 10 is not limited to this value and may be any specific numerical value. As shown in FIG. 1, in the present embodiment, ground is separately arranged for each of the primary circuit 13 and the secondary circuit 14.

The circuit configuration of the signal transmission device 10 will now be described in detail.

In the present embodiment, the signal transmission device 10 includes two capacitors 15 corresponding to two types of signals transmitted from the primary circuit 13 toward the secondary circuit 14. More specifically, the signal transmission device 10 includes a capacitor 15 that is used to transmit a first signal from the primary circuit 13 to the secondary circuit 14 and a capacitor 15 that is used to transmit a second signal from the primary circuit 13 to the secondary circuit 14. In the present embodiment, the first signal includes information about a rising edge of an external signal that is input to the signal transmission device 10. The second signal includes information about a falling edge of the external signal. The first signal and the second signal generate a pulse signal.

Hereinafter, for the sake of brevity, the capacitor 15 used to transmit the first signal is referred to as a “capacitor 15A.” The capacitor 15 used to transmit the second signal is referred to as a “capacitor 15B.” In the present embodiment, the capacitor 15A corresponds to a “first signal capacitor.” The capacitor 15B corresponds to a “second signal capacitor.”

The signal transmission device 10 includes primary signal lines 16A and 16B and secondary signal lines 17A and 17B.

The primary signal line 16A is configured to connect the primary circuit 13 and the capacitor 15A and transmit the first signal from the primary circuit 13 to the capacitor 15A. The primary signal line 16B is configured to connect the primary circuit 13 and the capacitor 15B and transmit the second signal from the primary circuit 13 to the capacitor 15B.

The secondary signal line 17A is configured to connect the capacitor 15A and the secondary circuit 14 and transmit the first signal from the capacitor 15A to the secondary circuit 14. The secondary signal line 17B is configured to connect the capacitor 15B and the secondary circuit 14 and transmit the second signal from the capacitor 15B to the secondary circuit 14.

As described above, the first signal is transmitted from the primary circuit 13 to the secondary circuit 14 sequentially through the primary signal line 16A, the capacitor 15A, and the secondary signal line 17A. The second signal is transmitted from the primary circuit 13 to the secondary circuit 14 sequentially through the primary signal line 16B, the capacitor 15B, and the secondary signal line 17B.

While transmitting the first signal from the primary circuit 13 to the secondary circuit 14, the capacitor 15A electrically insulates the primary circuit 13 from the secondary circuit 14. The capacitor 15A includes a first electrode 21A and a second electrode 22A. The first electrode 21A is connected to the primary signal line 16A. The second electrode 22A is connected to the secondary signal line 17A.

While transmitting the second signal from the primary circuit 13 to the secondary circuit 14, the capacitor 15B electrically insulates the primary circuit 13 from the secondary circuit 14. The capacitor 15B includes a first electrode 21B and a second electrode 22B. The first electrode 21B is connected to the primary signal line 16B. The second electrode 22B is connected to the secondary signal line 17B.

In the present embodiment, the insulation voltage of the capacitors 15A and 15B is, for example, in a range of 2500 Vrms to 7500 Vrms. The insulation voltage of the capacitors 15A and 15B may be in a range of 2500 Vrms to 5700 Vrms. However, the insulation voltage of the capacitors 15A and 15B is not limited to these values and may be any specific numerical value.

### Internal Configuration of Signal Transmission Device

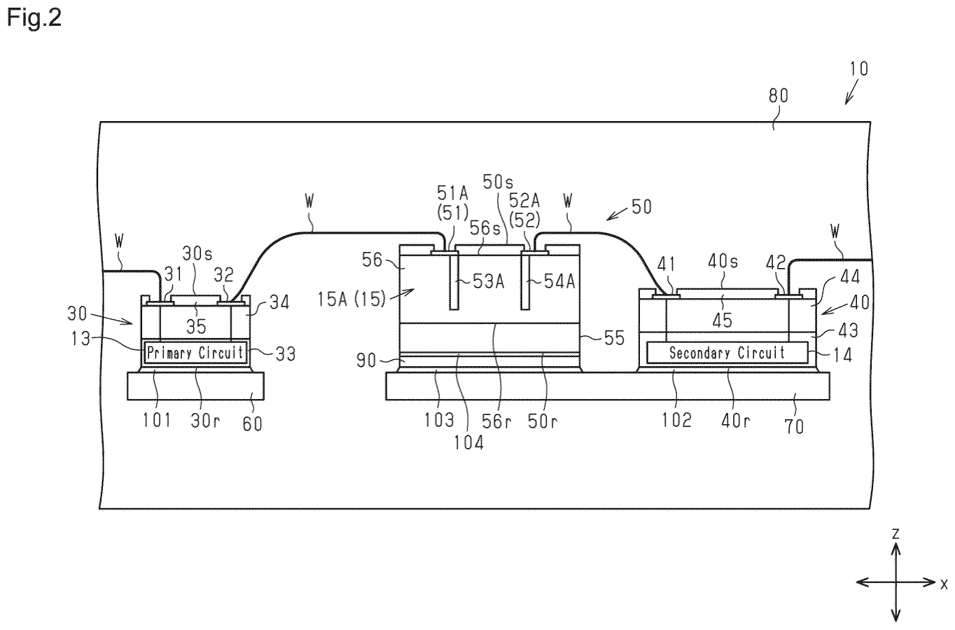

FIG. 2 is a schematic diagram showing an example of a cross-sectional structure of an internal configuration of a portion of the signal transmission device 10. As shown in FIG. 2, the signal transmission device 10 is a semiconductor device including multiple semiconductor chips arranged in a single package. Although not shown in the drawings, the package of the signal transmission device 10 is, for example, of a small outline (SO) type and, in the present embodiment, is a small outline package (SOP). The package type of the signal transmission device 10 may be changed in any manner.

The signal transmission device 10 includes the multiple semiconductor chips, namely, a first chip 30, a second chip 40, and an insulating chip 50. The signal transmission device 10 further includes a primary die pad 60 on which the first chip 30 is mounted, a secondary die pad 70 on which the second chip 40 is mounted, and an encapsulation resin 80 encapsulating the die pads 60 and 70 and the chips 30, 40, and 50. In the present embodiment, the primary die pad 60 corresponds to a “first mount frame,” and the secondary die pad 70 corresponds to a “mount frame” or a “second mount frame.”

The encapsulation resin 80 is formed from an electrically-insulative resin material and is, for example, formed from a black epoxy resin. The encapsulation resin 80 has the form of a rectangular plate having a thickness-wise direction aligned with the z-direction.

The primary die pad 60 and the secondary die pad 70 are each formed from a conductive material. In the present embodiment, the die pads 60 and 70 are formed from a material including copper (Cu). Alternatively, the die pads 60 and 70 may be formed from a material including other metal such as aluminum (Al). Furthermore, the material of the die pads 60 and 70 is not limited to a conductive material. In an example, the die pads 60 and 70 may be formed from ceramics such as alumina. That is, the die pads 60 and 70 may be formed from an electrically-insulative material. In the present embodiment, the die pads 60 and 70 are not exposed from the encapsulation resin 80.

As viewed in the z-direction, the primary die pad 60 and the secondary die pad 70 are arranged next to each other and separated from each other. As viewed in the z-direction, the arrangement direction of the primary die pad 60 and the secondary die pad 70 is referred to as an x-direction. As viewed in the z-direction, a direction orthogonal to the x-direction is referred to as a y-direction. The primary die pad 60 and the secondary die pad 70 are each flat. In the present embodiment, the secondary die pad 70 is greater than the primary die pad 60 in the length in the x-direction.

In the present embodiment, the insulating chip 50 is mounted on the secondary die pad 70. Thus, the insulating chip 50 and the second chip 40 are mounted on the secondary die pad 70. The second chip 40 and the insulating chip 50 are separated from each other in the x-direction. Thus, the chips 30, 40, and 50 are separated from each other in the x-direction. In the present embodiment, the chips 30, 40, and 50 are arranged in the x-direction in the order of the first chip 30, the insulating chip 50, and the second chip 40 in a direction from the primary die pad 60 toward the secondary die pad 70. That is, the insulating chip 50 is located between the first chip 30 and the second chip 40 in the x-direction.

The die pads 60 and 70 need to be separated from each other so that the signal transmission device 10 is set to a predetermined insulation voltage. In the present embodiment, as viewed in the z-direction, the distance between the primary die pad 60 and the secondary die pad 70 is greater than the distance between the second chip 40 and the insulating chip 50 in the x-direction. Therefore, as viewed in the z-direction, the distance between the first chip 30 and the insulating chip 50 in the x-direction is greater than the distance between the second chip 40 and the insulating chip 50 in the x-direction. In other words, the insulating chip 50 is located closer to the second chip 40 than to the first chip 30.

The first chip 30 includes a first substrate 33 on which the primary circuit 13 is formed. The first substrate 33 is, for example, a semiconductor substrate. In an example, the semiconductor substrate is formed from a material including silicon (Si). An interconnect layer 34 is formed on the first substrate 33. The interconnect layer 34 includes insulation films stacked in the z-direction, metal layers arranged between ones of the insulation films that are adjacent to each other in the z-direction, and vias connecting ones of the metal layers located at different positions in the z-direction. The metal layers and the vias form a wiring pattern of the first chip 30. The metal layers and the vias are, for example, electrically connected to the primary circuit 13. A protective film 35 is formed on the interconnect layer 34 to protect the interconnect layer 34. The protective film 35 is formed from an electrically-insulative material.

The first chip 30 includes a chip front surface 30s and a chip back surface 30r that face opposite directions in the z-direction. The first substrate 33 includes the chip back surface 30r. The protective film 35 includes the chip front surface 30s. The chip back surface 30r faces the primary die pad 60. First electrode pads 31 and second electrode pads 32 are arranged on a portion of the first chip 30 located toward the chip front surface 30s. More specifically, the electrode pads 31 and 32 are exposed from the chip front surface 30s. The protective film 35 covers the electrode pads 31 and 32. The protective film 35 includes openings that expose the electrode pads 31 and 32. The electrode pads 31 and 32 are, for example, electrically connected to the primary circuit 13 by the interconnect layer 34.

The first electrode pads 31 and the second electrode pads 32 are formed on a front surface of the interconnect layer 34. The front surface of the interconnect layer 34 refers to a surface of the interconnect layer 34 facing the same direction as the chip front surface 30s. As viewed in the z-direction, the first electrode pads 31 are arranged on the chip front surface 30s at a side opposite from the insulating chip 50 with respect to the center of the chip front surface 30s in the x-direction. Although not shown, the electrode pads 31 are separated from each other in the y-direction. The second electrode pads 32 are arranged on a portion of the chip front surface 30s located toward the insulating chip 50 with respect to the center of the chip front surface 30s in the x-direction. Although not shown, the second electrode pads 32 are separated from each other in the y-direction.

As shown in FIG. 2, the first chip 30 is bonded to the primary die pad 60 by a first bonding material 101. The first bonding material 101 is located between the chip back surface 30r of the first chip 30 and the primary die pad 60. The first bonding material 101 is a conductive bonding material such as solder paste or silver (Ag) paste.

The first bonding material 101 bonds the first substrate 33 of the first chip 30 and the primary die pad 60 and thus electrically connects the first substrate 33 and the primary die pad 60. Thus, the primary circuit 13 is electrically connected to the primary die pad 60 by the first bonding material 101. In the present embodiment, the primary die pad 60 is a ground. Thus, the primary circuit 13 is electrically connected to the ground.

The content of the first bonding material 101 may be changed in any manner and be, for example, an insulative bonding material. In this case, the primary circuit 13 may be electrically connected to the primary die pad 60 by a component (e.g., wire) other than the first bonding material 101.

The second chip 40 includes a second substrate 43 on which the secondary circuit 14 is formed. The second substrate 43 is, for example, a semiconductor substrate. In an example, the semiconductor substrate is formed from a material including Si. An interconnect layer 44 is formed on the second substrate 43. The interconnect layer 44 includes insulation films stacked in the z-direction, metal layers arranged between ones of the insulation films that are adjacent to each other in the z-direction, and vias connecting ones of the metal layers located at different positions in the z-direction. The metal layers and the vias from a wiring pattern of the second chip 40. The metal layers and the vias are, for example, electrically connected to the secondary circuit 14. A protective film 45 is formed on the interconnect layer 44 to protect the interconnect layer 44. The protective film 45 is formed from an electrically-insulative material.

The second chip 40 includes a chip front surface 40s and a chip back surface 40r that face opposite directions in the z-direction. The second substrate 43 includes the chip back surface 40r. The protective film 45 includes the chip front surface 40s. The chip back surface 40r faces the secondary die pad 70. The chip back surface 40r faces the same direction as the chip back surface 30r of the first chip 30. The chip front surface 40s faces the same direction as the chip front surface 30s of the first chip 30. First electrode pads 41 and second electrode pads 42 are arranged on a portion of the second chip 40 located toward the chip front surface 40s. More specifically, the electrode pads 41 and 42 are exposed from the chip front surface 40s. The protective film 45 covers the electrode pads 41 and 42. The protective film 45 includes openings that expose the electrode pads 41 and 42. The electrode pads 41 and 42 are, for example, electrically connected to the secondary circuit 14 by the interconnect layer 44

The first electrode pads 41 and the second electrode pads 42 are formed on a front surface of the interconnect layer 44. The front surface of the interconnect layer 44 refers to a surface of the interconnect layer 44 facing the same direction as the chip front surface 40s. As viewed in the z-direction, the first electrode pads 41 are arranged on a portion of the chip front surface 40s located toward the insulating chip 50 with respect to the center of the chip front surface 40s in the x-direction. Although not shown, the first electrode pads 41 are separated from each other in the y-direction. The second electrode pads 42 are arranged on the chip front surface 40s at a side opposite from the insulating chip 50 with respect to the center of the chip front surface 40s in the x-direction. Although not shown, the second electrode pads 42 are separated from each other in the y-direction.

The second chip 40 is bonded to the secondary die pad 70 by a second bonding material 102. More specifically, the second bonding material 102 is located between the chip back surface 40r and the secondary die pad 70. The second bonding material 102 bonds the chip back surface 40r and the secondary die pad 70. The second bonding material 102 is a conductive bonding material such as solder paste or Ag paste. In the present embodiment, the second bonding material 102 has, for example, the same content as the first bonding material 101.

The content of the second bonding material 102 may be changed in any manner and be, for example, a conductive bonding material that differs from the material of the first bonding material 101. The second bonding material 102 may be an insulative bonding material. In this case, the secondary circuit 14 may be electrically connected to the secondary die pad 70 by a component (e.g., wire) other than the second bonding material 102.

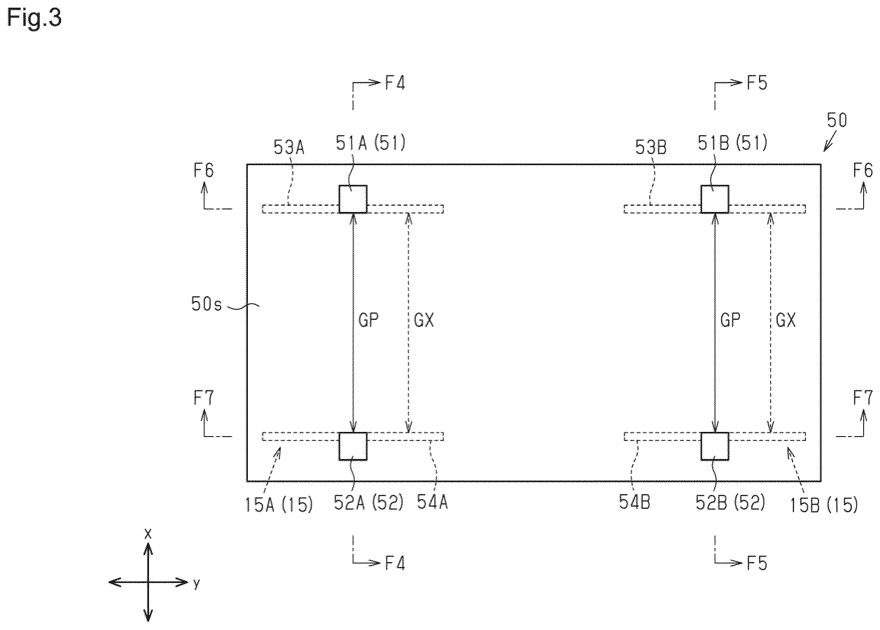

The insulating chip 50 includes the capacitors 15A and 15B (refer to FIG. 1). As shown in FIG. 3, as viewed in the z-direction, the insulating chip 50 is rectangular and includes long sides and short sides. In the present embodiment, as viewed in the z-direction, the insulating chip 50 is mounted on the secondary die pad 70 so that the long sides extend in the y-direction and the short sides extend in the x-direction.

As shown in FIG. 2, the insulating chip 50 includes a chip front surface 50s and a chip back surface 50r that face opposite directions in the z-direction. The chip back surface 50r faces the secondary die pad 70. More specifically, the chip back surface 50r faces the same direction as the chip back surface 40r of the second chip 40. The chip front surface 50s faces the same direction as the chip front surface 40s of the second chip 40.

The insulating chip 50 includes multiple (in the present embodiment, two) first electrode pads 51 and multiple (in the present embodiment, two) second electrode pads 52. The electrode pads 51 and 52 are arranged toward the chip front surface 50s. More specifically, as viewed in the z-direction, the electrode pads 51 and 52 are exposed from the chip front surface 50s. In the present embodiment, the electrode pads 51 and 52 are formed from a material including aluminum (Al). The material forming the electrode pads 51 and 52 may be changed in any manner and may include Cu, titanium (Ti), titanium nitride (TiN), tungsten (W), nickel (Ni), palladium (Pd), or the like.

The first electrode pads 51 are arranged on a portion of the chip front surface 50s located toward the first chip 30 with respect to the center of the chip front surface 50s in the x-direction. The second electrode pads 52 are arranged on a portion of the chip front surface 50s located toward the second chip 40 with respect to the center of the chip front surface 50s in the x-direction.

Wires W are connected to each of the first chip 30, the second chip 40, and the insulating chip 50. The first chip 30 and the insulating chip 50 are electrically connected by the wires W. The second chip 40 and the insulating chip 50 are electrically connected by the wires W. Each wire W is a bonding wire formed by a wire bonder and is, for example, formed from a conductor such as gold (Au), Al, Cu, or the like.

The first electrode pads 31 of the first chip 30 are separately connected by wires W to primary leads, which are not shown. The primary leads are parts forming the primary terminals 11 shown in FIG. 1. Thus, the primary circuit 13 is electrically connected to the primary terminals 11.

In the present embodiment, the primary leads and the primary die pad 60 are formed from the same material. The primary leads and the primary die pad 60 may be formed integrally. The primary leads are arranged separately from the primary die pad 60 at a side of the primary die pad 60 opposite from the secondary die pad 70. The primary leads include portions projecting outward from the encapsulation resin 80. The portions of the primary leads projecting outward from the encapsulation resin 80 are used as external terminals of the signal transmission device 10.

The second electrode pads 32 of the first chip 30 are separately connected to the first electrode pads 51 of the insulating chip 50 by the wires W. Thus, the primary circuit 13 is electrically connected to the capacitors 15A and 15B (refer to FIG. 1). In other words, the primary signal lines 16A and 16B (refer to FIG. 1) include the interconnect layer 34 of the first chip 30, the second electrode pads 32, the wires W, and the first electrode pads 51.

The second electrode pads 52 of the insulating chip 50 are separately connected to the first electrode pads 41 of the second chip 40 by the wires W. Thus, the capacitors 15A and 15B are electrically connected to the secondary circuit 14. In other words, the secondary signal lines 17A and 17B (refer to FIG. 1) include the second electrode pads 52, the wires W, the first electrode pads 41 of the second chip 40, and the interconnect layer 44.

The second electrode pads 42 of the second chip 40 are separately connected by wires W to secondary leads, which are not shown. The secondary leads are parts forming the secondary terminals 12 shown in FIG. 1. Thus, the secondary circuit 14 is electrically connected to the secondary terminals 12.

In the present embodiment, the secondary leads and the secondary die pad 70 are formed from the same material. The secondary leads and the secondary die pad 70 may be formed integrally. Moreover, the primary leads, the primary die pad 60, the secondary leads, and the secondary die pad 70 may be formed integrally. The secondary leads are arranged separately from the secondary die pad 70 at a side of the secondary die pad 70 opposite from the primary die pad 60. The secondary leads include portions projecting outward from the encapsulation resin 80. The portions of the secondary leads projecting outward from the encapsulation resin 80 are used as external terminals of the signal transmission device 10.

### Detailed Structure of Insulating Chip

The structure of the insulating chip 50 will now be described in detail with reference to FIGS. 2 to 7. In the description hereafter, for the sake of convenience, the two first electrode pads 51 are referred to as a first electrode pad 51A and a first electrode pad 51B, and the two second electrode pads 52 are referred to as a second electrode pad 52A and the second electrode pad 52B.

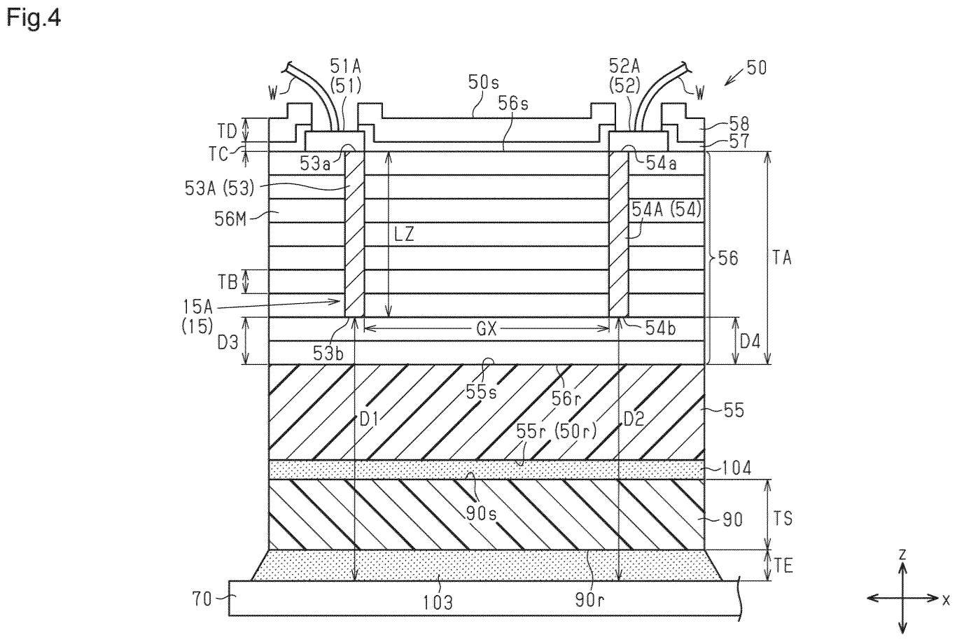

FIG. 3 is a schematic plan view showing the planar structure of the insulating chip 50. FIGS. 4 to 7 are schematic cross-sectional views showing a cross-sectional structure taken along respective indicating lines shown in FIG. 3. FIGS. 4 to 7 do not show the hatching lines of some of the components for simplicity and clarity. In the following description, a direction from the chip back surface 50r toward the chip front surface 50s of the insulating chip 50 is referred to as an upward direction. A direction from the chip front surface 50s toward the chip back surface 50r is referred to as a downward direction.

As shown in FIG. 3, the insulating chip 50 is a single chip in which the two capacitors 15A and 15B are integrated. The insulating chip 50 is separate from the first chip 30 and the second chip 40 (refer to FIG. 2) and is dedicated to the two capacitors 15A and 15B.

The two capacitors 15A and 15B are separated from each other in the y-direction. In other words, as viewed in the z-direction, the two capacitors 15A and 15B are separated from each other in a direction in which the long sides of the insulating chip 50 extend.

The capacitor 15A includes a first electrode plate 53A and a second electrode plate 54A opposed to each other in the x-direction. The first electrode plate 53A corresponds to the first electrode 21A (refer to FIG. 1) of the capacitor 15A. The second electrode plate 54A corresponds to the second electrode 22A (refer to FIG. 1) of the capacitor 15A. The capacitor 15B includes a first electrode plate 53B and a second electrode plate 54B opposed to each other in the x-direction. The first electrode plate 53B corresponds to a first electrode 21B (refer to FIG. 1) of the capacitor 15B. The second electrode plate 54B corresponds to a second electrode 22B (refer to FIG. 1) of the capacitor 15B. In the present embodiment, the two capacitors 15A and 15B have the same structure. Thus, as viewed in the z-direction, the first electrode plate 53A (53B) and the second electrode plate 54A (54B) are separated from each other in a direction in which the short sides of the insulating chip 50 extend. In other words, as viewed in the z-direction, the first electrode plate 53A (53B) and the second electrode plate 54A (54B) are opposed to each other in a direction orthogonal to the arrangement direction of the two capacitors 15A and 15B.

In the present embodiment, the first electrode plates 53A and 53B and the second electrode plates 54A and 54B are formed from a material including Cu. The material forming the first electrode plates 53A and 53B and the second electrode plates 54A and 54B may be changed in any manner and may include, for example, Al, W, or the like. The first electrode plates 53A and 53B and the second electrode plates 54A and 54B may be formed from a material including a least one of Cu, Al, and W. Alternatively, the first electrode plates 53A and 53B and the second electrode plates 54A and 54B may be formed from a material including at least one of Ti and tantalum (Ta).

As shown in FIG. 2, in the capacitor 15A, the first electrode plate 53A is located closer to the first chip 30 in the x-direction than the center of the insulating chip 50 is. The second electrode plate 54A is located closer to the second chip 40 in the x-direction than the center of the insulating chip 50 is.

As shown in FIG. 3, as viewed in the z-direction, the first electrode plate 53A extends out from opposite sides of the first electrode pad 51A in the y-direction. That is, the length of the first electrode plate 53A in the y-direction is greater than the length of the first electrode pad 51A in the y-direction. In the present embodiment, as viewed in the z-direction, the first electrode pad 51A overlaps a central portion of the first electrode plate 53A in the y-direction. The position of the first electrode pad 51A relative to the first electrode plate 53A in the y-direction may be changed in any manner.

The first electrode plate 53A is electrically connected to the first electrode pad 51A. The first electrode pad 51A is directly connected to the first electrode plate 53A. More specifically, as viewed in the z-direction, the first electrode pad 51A is arranged at a position to overlap the first electrode plate 53A. In the z-direction, the first electrode pad 51A is in contact with the first electrode plate 53A.

The first electrode plate 53A is smaller than the first electrode pad 51A in length in the x-direction. As viewed in the z-direction, the first electrode pad 51A is arranged so as not to extend toward the second electrode plate 54A beyond the first electrode plate 53A. The first electrode pad 51A includes two ends in the x-direction. One of the two ends located closer to the second electrode plate 54A is arranged at a position to overlap the first electrode plate 53A as viewed in the z-direction. In the present embodiment, one of two side surfaces of the first electrode pad 51A in the x-direction located toward the second electrode plate 54A is flush with one of two side surfaces of the first electrode plate 53A in the x-direction located toward the second electrode plate 54A. Thus, as shown in FIG. 2, the first electrode pad 51A is arranged to extend out from the first electrode plate 53A toward the first chip 30. Therefore, as shown in FIG. 3, a distance GX between the first electrode plate 53A and the second electrode plate 54A in the x-direction is equal to a distance GP between the first electrode pad 51A and the second electrode pad 52A in the x-direction. The distance GX may be referred to as an opposing distance between the first electrode plate 53A and the second electrode plate 54A.

As viewed in the z-direction, the second electrode plate 54A extends out from opposite sides of the second electrode pad 52A in the y-direction. That is, the second electrode plate 54A is larger than the second electrode pad 52A in dimension in the y-direction. In the present embodiment, the second electrode plate 54A is equal to the first electrode plate 53A in dimension in the y-direction. The second electrode plate 54A is smaller than the second electrode pad 52A in length in the x-direction. In the present embodiment, the second electrode plate 54A is equal to the first electrode plate 53A in length in the x-direction. As shown in FIG. 4, the second electrode plate 54A is equal to the first electrode plate 53A in length in the z-direction.

When the difference between the second electrode plate 54A and the first electrode plate 53A in length in the y-direction is, for example, within 10% of the length of the first electrode plate 53A in the y-direction, it is considered that the second electrode plate 54A is equal to the first electrode plate 53A in length in the y-direction. When the difference between the second electrode plate 54A and the first electrode plate 53A in length in the x-direction is, for example, within 10% of the length of the first electrode plate 53A in the x-direction, it is considered that the second electrode plate 54A is equal to the first electrode plate 53A in length in the x-direction.

In the present embodiment, as viewed in the z-direction, the second electrode pad 52A overlaps a central portion of the second electrode plate 54A in the y-direction. The position of the second electrode pad 52A relative to the second electrode plate 54A in the y-direction may be changed in any manner.

The second electrode plate 54A is electrically connected to the second electrode pad 52A. The second electrode pad 52A is directly connected to the second electrode plate 54A. More specifically, as viewed in the z-direction, the second electrode pad 52A is arranged at a position to overlap the second electrode plate 54A. In the z-direction, the second electrode pad 52A is in contact with the second electrode plate 54A. As viewed in the z-direction, the second electrode pad 52A is arranged so as not to extend toward the first electrode plate 53A beyond the second electrode plate 54A. The second electrode pad 52A includes two ends in the x-direction. One of the two ends located closer to the first electrode plate 53A is arranged at a position to overlap the second electrode plate 54A as viewed in the z-direction. In the present embodiment, one of two side surfaces of the second electrode pad 52A in the x-direction located toward the first electrode plate 53A is flush with one of two side surfaces of the second electrode plate 54A in the x-direction located toward the first electrode plate 53A. Thus, as shown in FIG. 2, the second electrode pad 52A is arranged to extend out from the second electrode plate 54A toward the second chip 40.

As shown in FIG. 3, the arrangement manner of the first electrode plate 53B and the second electrode plate 54B in the capacitor 15B and the arrangement relationship of the first electrode pad 51B and the second electrode pad 52B with the first electrode plate 53B and the second electrode plate 54B corresponding to the capacitor 15B are the same as those of the capacitor 15A and thus will not be described in detail.

As shown in FIG. 4, the insulating chip 50 includes a substrate 55 and an element insulation layer 56 formed on the substrate 55.

The substrate 55 is formed of, for example, a semiconductor substrate. In the present embodiment, the substrate 55 includes a semiconductor substrate formed from a material including Si. As the semiconductor substrate, a wide-bandgap semiconductor or a compound semiconductor may be used for the substrate 55. The substrate 55 may be an insulating substrate that is formed from a material including glass or an insulating substrate that is formed from a material including ceramics such as alumina instead of a semiconductor substrate.

The wide-bandgap semiconductor is a semiconductor substrate having a band gap that is greater than or equal to 2.0 eV. The wide-bandgap semiconductor may be silicon carbide (SiC). The compound semiconductor may be a group III-V compound semiconductor. The compound semiconductor may include at least one of aluminum nitride (AlN), indium nitride (InN), gallium nitride (GaN), and gallium arsenide (GaAs).

The substrate 55 includes a substrate front surface 55s and a substrate back surface 55r that face opposite directions in the z-direction. Insulation films 56M are stacked on the substrate front surface 55s in the z-direction. In the present embodiment, the element insulation layer 56 includes the insulation films 56M stacked on one another. Thus, the z-direction is a thickness-wise direction of the element insulation layer 56. The phase “viewed in the z-direction” includes the meaning of “viewed in the thickness-wise direction of the element insulation layer 56.”

Each of the insulation films 56M is, for example, an interlayer insulation film and is an oxide film formed from a material including silicon oxide (SiO₂). The thickness of the insulation film 56M may be, for example, in a range of 500 nm to 5000 nm. In the present embodiment, the thickness of the insulation film 56M is, for example, approximately 2000 nm.

The element insulation layer 56 includes a front surface 56s and a back surface 56r. The front surface 56s faces the same direction as the substrate front surface 55s of the substrate 55. The back surface 56r faces the same direction as the substrate back surface 55r of the substrate 55. The front surface 56s of the element insulation layer 56 is the front surface of the uppermost the insulation film 56M among the insulation films 56M stacked in the z-direction. The back surface 56r of the element insulation layer 56 is the back surface of the lowermost insulation film 56M among the insulation films 56M stacked in the z-direction. The back surface 56r of the element insulation layer 56 is opposed to the substrate front surface 55s of the substrate 55. More specifically, the back surface 56r of the element insulation layer 56 is in contact with the substrate front surface 55s of the substrate 55.

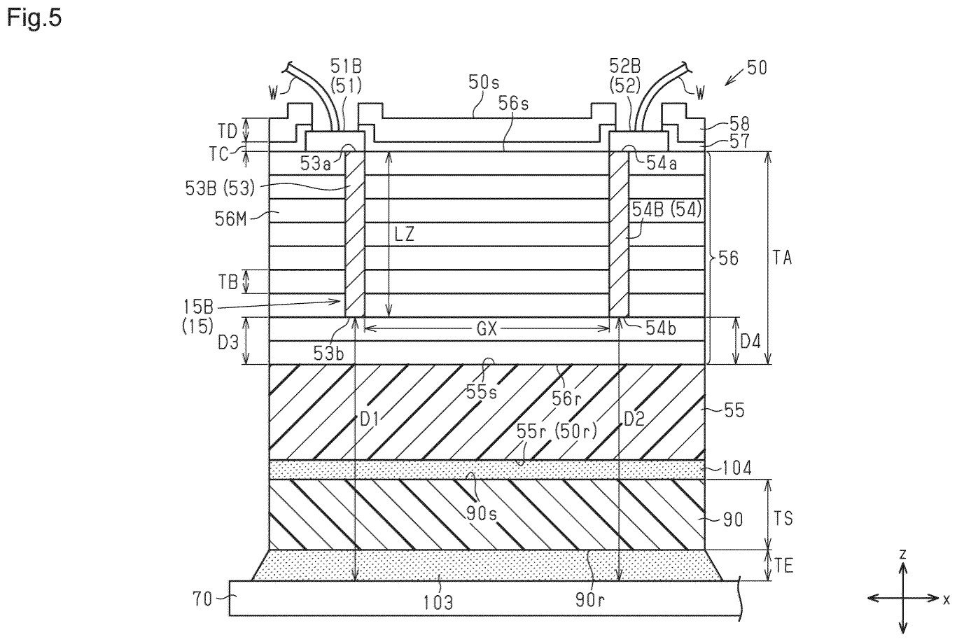

As shown in FIGS. 4 and 5, the first electrode pads 51A and 51B and the second electrode pads 52A and 52B are arranged on the front surface 56s of the element insulation layer 56. That is, the first electrode pads 51A and 51B and the second electrode pads 52A and 52B are arranged on the element insulation layer 56.

The insulating chip 50 further includes a protective film 57 formed on the front surface 56s of the element insulation layer 56 and a passivation film 58 formed on the protective film 57. The protective film 57 protects the element insulation layer 56 and is formed from a material including, for example, SiO₂. The passivation film 58 is a surface protective film of the insulating chip 50 and is formed from a material including, for example, SiN. The passivation film 58 includes the chip front surface 50s of the insulating chip 50.

The first electrode pads 51A and 51B and the second electrode pads 52A and 52B are covered by the protective film 57 and the passivation film 58. The protective film 57 and the passivation film 58 include openings that expose the first electrode pads 51A and 51B and the second electrode pads 52A and 52B. Thus, the electrode pads 51A, 51B, 52A, and 52B each include an exposed surface for connecting a wire W.

As shown in FIGS. 4 to 7, the capacitors 15A and 15B are arranged in the element insulation layer 56. More specifically, the first electrode plate 53A and the second electrode plate 54A of the capacitor 15A and the first electrode plate 53B and the second electrode plate 54B of the capacitor 15B are arranged in the element insulation layer 56.

As shown in FIG. 4, the first electrode plate 53A and the second electrode plate 54A are embedded in the element insulation layer 56. More specifically, the first electrode plate 53A and the second electrode plate 54A extend through two or more of the insulation films 56M in the z-direction. The first electrode plate 53A and the second electrode plate 54A are located above the substrate front surface 55s of the substrate 55 in the z-direction. Therefore, one or more of the insulation films 56M are located between the first electrode plate 53A and the substrate front surface 55s and between the second electrode plate 54A and the substrate front surface 55s in the z-direction. Thus, the first electrode plate 53A and the second electrode plate 54A are insulated from the substrate 55. As shown in FIG. 4, the first electrode plate 53A and the second electrode plate 54A are each flat and have a thickness extending in the x-direction.

The first electrode plate 53A and the second electrode plate 54A are opposed to each other in a first direction that is a direction orthogonal to the thickness-wise direction (z-direction) of the element insulation layer 56. The first electrode plate 53A and the second electrode plate 54A are opposed to each other in the x-direction. That is, the x-direction corresponds to “the first direction.”

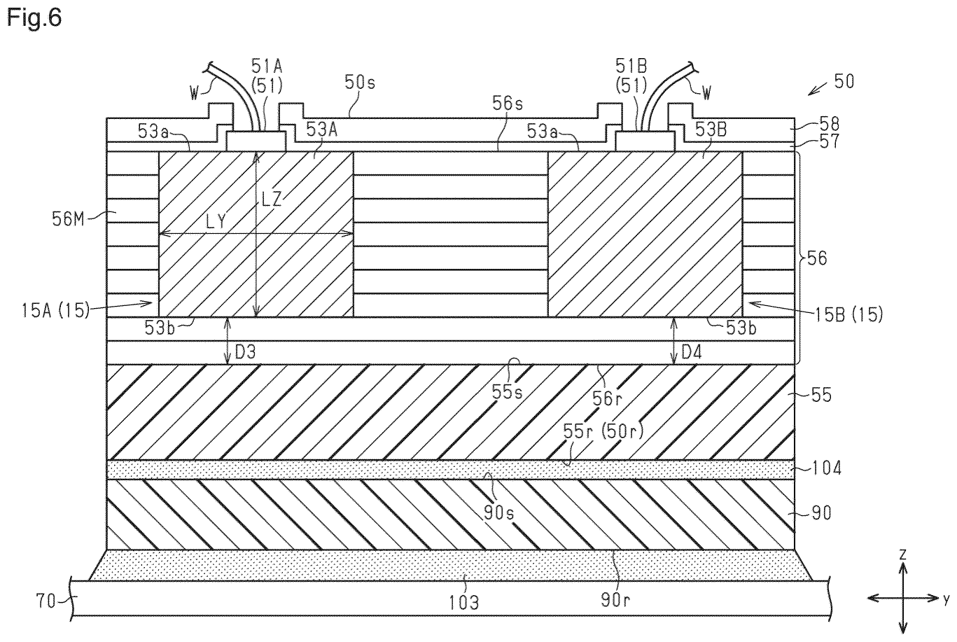

The element insulation layer 56 includes a portion (inter-electrode insulation film) located between the first electrode plate 53A and the second electrode plate 54A in the x-direction. In other words, the first electrode plate 53A and the second electrode plate 54A are opposed to each other via the portion (inter-electrode insulation film) of the element insulation layer 56. In an example, the distance GX between the first electrode plate 53A and the second electrode plate 54A in the x-direction is greater than a length LZ of the first electrode plate 53A in the z-direction. The distance GX between the first electrode plate 53A and the second electrode plate 54A in the x-direction is also greater than a length LY (refer to FIG. 6) of the first electrode plate 53A in the y-direction. The distance GX between the first electrode plate 53A and the second electrode plate 54A in the x-direction is greater than a distance D3 between the first electrode plate 53A and the substrate front surface 55s of the substrate 55 in the z-direction. The distance GX between the first electrode plate 53A and the second electrode plate 54A in the x-direction is also greater than a distance D4 between the second electrode plate 54A and the substrate front surface 55s of the substrate 55 in the z-direction. In the present embodiment, the distance GX between the first electrode plate 53A and the second electrode plate 54A in the x-direction is greater than a thickness TA of the element insulation layer 56.

The distance D3 between the first electrode plate 53A and the substrate front surface 55s of the substrate 55 in the z-direction is defined by a distance between an electrode lower surface 53b of the first electrode plate 53A and the substrate front surface 55s of the substrate 55 in the z-direction. Alternatively, the distance D3 may be defined by a distance between the electrode lower surface 53b of the first electrode plate 53A and the back surface 56r of the element insulation layer 56 in the z-direction. The distance D4 between the second electrode plate 54A and the substrate front surface 55s of the substrate 55 in the z-direction is defined by a distance between an electrode lower surface 54b of the second electrode plate 54A and the substrate front surface 55s of the substrate 55 in the z-direction. Alternatively, the distance D4 may be defined by a distance between the electrode lower surface 54b of the second electrode plate 54A and the back surface 56r of the element insulation layer 56 in the z-direction.

The distance GX may be changed in any manner in accordance with the insulation voltage necessary for the capacitor 15A. The insulation voltage necessary for the capacitor 15A depends on the distance GX between the first electrode plate 53A and the second electrode plate 54A. A distance between electrodes corresponding to the insulation voltage necessary for the capacitor 15A is referred to as a reference distance. In the present embodiment, the ratio of the distance GX to the reference distance is, for example, in a range of 1.0 to 2.0. The ratio is preferably, for example, 1.6. The distance GX between the first electrode plate 53A and the second electrode plate 54A is set to be greater than the reference distance taking into consideration a safety margin. An increase in the distance GX decreases the capacitance of the capacitor 15A. An increase in the distance GX may increase effects on the first electrode plate 53A or the second electrode plate 54A received from a conductive member located outside the insulating chip 50. When such effects are considered, the insulating chip 50 will be enlarged. Therefore, it is preferred that the distance GX be set to be close to the reference distance in order to minimize decreases in the capacitance of the capacitor 15A and enlargement of the insulating chip 50.

The first electrode plate 53A includes an electrode upper surface 53a and the electrode lower surface 53b. The electrode upper surface 53a is exposed from the front surface 56s of the element insulation layer 56. In the present embodiment, the electrode upper surface 53a is flush with the front surface 56s of the element insulation layer 56. The electrode upper surface 53a includes a portion in contact with the first electrode pad 51A. The protective film 57 covers the remaining portion of the electrode upper surface 53a excluding the portion in contact with the first electrode pad 51A. The electrode lower surface 53b is in contact with a surface of an insulation film 56M located relatively close to the substrate 55 among the insulation films 56M.

The second electrode plate 54A includes an electrode upper surface 54a and the electrode lower surface 54b. The electrode upper surface 54a is exposed from the front surface 56s in the element insulation layer 56. In the present embodiment, the electrode upper surface 54a is flush with the front surface 56s of the element insulation layer 56. The electrode upper surface 54a includes a portion in contact with the second electrode pad 52A. The protective film 57 covers the remaining portion of the electrode upper surface 54a excluding the portion in contact with the second electrode pad 52A. The electrode lower surface 54b is in contact with a surface of an insulation film 56M located relatively close to the substrate 55 among the insulation films 56M.

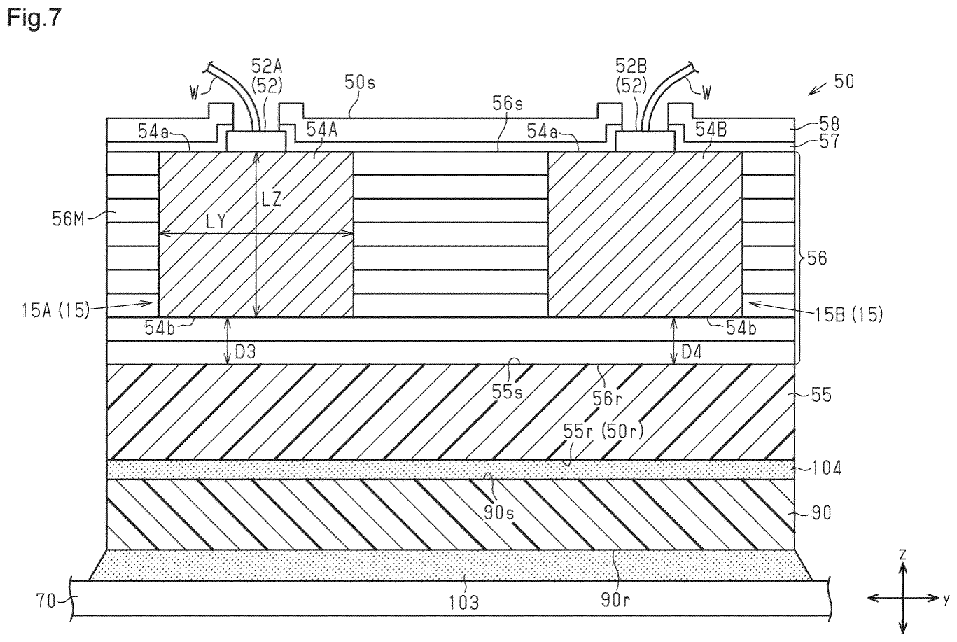

As shown in FIGS. 6 and 7, as viewed in the x-direction, the first electrode plate 53A and the second electrode plate 54A are each rectangular. The length LY of the first electrode plate 53A in the y-direction is larger than the length LZ of the first electrode plate 53A in the z-direction. In other words, the length LZ of the first electrode plate 53A in the z-direction is smaller than the length LY of the first electrode plate 53A in the y-direction. Since the first electrode plate 53A is plate-shaped and extends in a direction (y-direction) orthogonal to the thickness-wise direction (z-direction) of the element insulation layer 56, the length LY of the first electrode plate 53A in the y-direction may be increased without regard for the thickness TA of the element insulation layer 56. Therefore, while the length LZ of the first electrode plate 53A in the z-direction is decreased, the length LY of the first electrode plate 53A in the y-direction may be increased. As a result, while a decrease in the capacitance of the capacitor 15A is limited, the thickness TA of the element insulation layer 56 is decreased.

In the present embodiment, the length LY is smaller than the thickness TA of the element insulation layer 56. The length LZ of the first electrode plate 53A in the z-direction is smaller than the thickness TA of the element insulation layer 56. In an example, the length LZ is greater than the distance D3 between the first electrode plate 53A and the substrate front surface 55s of the substrate 55 in the z-direction.

The length LY of the first electrode plate 53A in the y-direction may be changed in any manner. In an example, the length LY may be smaller than or equal to the length LZ of the first electrode plate 53A in the z-direction. In an example, the length LY may be larger than or equal to the thickness TA of the element insulation layer 56. The length LZ of the first electrode plate 53A in the z-direction may be less than or equal to the distance D3 between the first electrode plate 53A and the substrate front surface 55s of the substrate 55 in the z-direction. The second electrode plate 54A and the first electrode plate 53A are identical in size and shape.

As shown in FIGS. 5 to 7, the shape and size of the first electrode plate 53B and the second electrode plate 54B in the capacitor 15B and the relationship of the first electrode plate 53B and the second electrode plate 54B with the element insulation layer 56 are the same as those of the capacitor 15A and thus will not be described.

As shown in FIGS. 4 to 7, the insulating chip 50 is mounted on the secondary die pad 70. More specifically, the insulating chip 50 is mounted on the secondary die pad 70 via an insulating substrate 90. In other words, the insulating substrate 90 is located between the insulating chip 50 and the secondary die pad 70. The insulating substrate 90 is bonded to the secondary die pad 70 by a third bonding material 103. The insulating chip 50 is bonded to the insulating substrate 90 by a fourth bonding material 104. The third bonding material 103 and the fourth bonding material 104 each are, for example, an insulative bonding material. The insulating substrate 90 corresponds to an “insulation member.” The third bonding material 103 corresponds to a “first insulative bonding material.” The fourth bonding material 104 corresponds to a “second insulative bonding material.”

The insulating substrate 90 is formed by an insulating substrate including alumina or an insulating substrate including glass. The insulating substrate 90 may be formed from a resin material.

As shown in FIGS. 4 and 5, the insulating substrate 90 has a thickness TS that is greater than the distance D3 between the first electrode plate 53A (53B) and the substrate 55 in the z-direction. The thickness TS of the insulating substrate 90 is greater than the distance D4 between the second electrode plate 54A (54B) and the substrate 55 in the z-direction. The thickness TS of the insulating substrate 90 is defined by a distance between the front surface 90s and the back surface 90r of the insulating substrate 90 in the z-direction. The front surface 90s of the insulating substrate 90 is in contact with the fourth bonding material 104. The back surface 90r is in contact with the third bonding material 103.

As described above, the insulating chip 50 is mounted on the secondary die pad 70 via the insulating substrate 90. Thus, a distance D1 between the first electrode plate 53A (53B) of the capacitor 15A (15B) and the secondary die pad 70 is, for example, greater than the length LZ of the first electrode plate 53A (53B) in the z-direction. The distance D1 is greater than the thickness TA of the element insulation layer 56. The distance D1 is greater than or equal to the distance GX between the first electrode plate 53A and the second electrode plate 54A in the x-direction. In the present embodiment, the distance D1 is greater than the distance GX. A distance D2 between the second electrode plate 54A (54B) of the capacitor 15A (15B) and the secondary die pad 70 is equal to the distance D1.

The thickness TS of the insulating substrate 90 and the distances D1 and D2 may be changed in any manner. The thickness TS of the insulating substrate 90 may be, for example, less than or equal to the distance D3 between the first electrode plate 53A (53B) and the substrate 55 in the z-direction. The thickness TS may be less than or equal to the distance D4 between the second electrode plate 54A (54B) and the substrate 55 in the z-direction. The distances D1 and D2 may be less than the distance GX between the first electrode plate 53A and the second electrode plate 54A in the x-direction. In other words, the distance GX may be greater than the distances D1 and D2.

As shown in FIG. 2, the insulating chip 50 is mounted on the secondary die pad 70 via the insulating substrate 90. Thus, the distance between the secondary die pad 70 and the substrate 55 of the insulating chip 50 in the z-direction is greater than the distance between the secondary die pad 70 and the second substrate 43 of the second chip 40 in the z-direction. Also, the distance between the secondary die pad 70 and the substrate 55 of the insulating chip 50 in the z-direction is greater than the distance between the primary die pad 60 and the first substrate 33 of the first chip 30 in the z-direction.

### Method for Manufacturing Insulating Chip and Signal Transmission Device

An example of a method for manufacturing the insulating chip 50 of the present embodiment and an example of a method for manufacturing the signal transmission device 10 will now be described briefly. Steps of simultaneously forming multiple insulating chips 50 will be described below.

The method for manufacturing the insulating chip 50 includes a wafer preparing step, a first insulation layer forming step, a capacitor forming step, an electrode pad forming step, a second insulation layer forming step, and a singulating step.

In the wafer preparing step, a semiconductor wafer that forms the substrate 55 is prepared. The semiconductor wafer is formed from, for example, a material including Si. The semiconductor wafer is sized so that multiple insulating chips 50 are formed on the semiconductor wafer.

In the first insulation layer forming step, an element insulation layer is formed on the semiconductor wafer. More specifically, insulation films formed from a material including SiO₂ are stacked to form the element insulation layer. The insulation films form the insulation films 56M (refer to FIG. 4). The element insulation layer is formed, for example, on the entirety of a front surface of the semiconductor wafer. The element insulation layer is an insulation layer that forms the element insulation layer 56 (refer to FIG. 4).

In the capacitor forming step, multiple (in the present embodiment, four) trenches are formed to extend through the stacked insulation films in the thickness-wise direction of the element insulation layer. The trenches are separated from each other in a direction orthogonal to the thickness-wise direction of the element insulation layer. The trenches are formed so that one or more of the insulation films are located between the bottom of the trenches and the semiconductor wafer. The trenches are filled with a conductive material. This forms the first electrode plate 53A and the second electrode plate 54A of the capacitor 15A and the first electrode plate 53B and the second electrode plate 54B of the capacitor 15B. In the present embodiment, the conductive material is Cu. Alternatively, W, Ti, Al, Ta, or the like may be used as the conductive material.

In the electrode pad forming step, on the front surface of the element insulation layer, the first electrode pad 51A (51B) is formed on the first electrode plate 53A (53B), and the second electrode pad 52A (52B) is formed on the second electrode plate 54A (54B). The electrode pads 51A (51B) and 52A (52B) are formed from a material including, for example, Al. Alternatively, the electrode pads 51A (51B) and 52A (52B) may be formed from a material including Ti, TiN, W, Cu, Ni, Pd, or the like.

In the second insulation layer forming step, a protective film is formed. The protective film is an insulation film that forms the protective film 57 (refer to FIG. 4) and is formed on the entirety of a front surface of the element insulation layer. The protective film is formed from, for example, a material including SiO₂. Then, a passivation film is formed. The passivation film is an oxide film that forms the passivation film 58 (refer to FIG. 4) and is formed on the entirety of a front surface of the protective film. The passivation film is formed from, for example, a material including SiN. Openings that expose the electrode pads 51A, 51B, 52A, and 52B are formed in the protective film and the passivation film. In forming the protective film and the passivation film, a mask may be used to form the openings that expose the electrode pads 51A, 51B, 52A, and 52B.

In the singulating step, the semiconductor wafer on which the element insulation layer is formed is cut to have the size of the insulating chip 50. As a result, the insulating chip 50 is singulated. The steps described above manufacture the insulating chip 50.

The method for manufacturing the signal transmission device 10 includes a frame preparing step, a chip mounting step, a wire forming step, a resin layer forming step, a separating step, and a terminal forming step.

In the frame preparing step, a frame that forms the primary leads, the secondary leads, the primary die pad 60, and the secondary die pad 70 (refer to FIG. 2) is prepared. In an example, the frame is a single plate formed from a material including Cu. Pressing or etching is performed on the frame to form the primary leads, the secondary leads, the primary die pad 60, and the secondary die pad 70. In this step, the primary leads, the secondary leads, the primary die pad 60, and the secondary die pad 70 are connected to the frame.

In the chip mounting step, the first chip 30 is mounted on the primary die pad 60 by die bonding, and the second chip 40 and the insulating chip 50 are mounted on the secondary die pad 70 by die bonding.

More specifically, the first bonding material 101 is applied to a portion of the primary die pad 60 on which the first chip 30 will be mounted. The second bonding material 102 is applied to a portion of the second chip 40 on which the secondary die pad 70 will be mounted. The first bonding material 101 and the second bonding material 102 are a conductive bonding material. The first chip 30 is mounted on the first bonding material 101. The second chip 40 is mounted on the second bonding material 102. The first bonding material 101 and the second bonding material 102 are solidified. In an example, when the bonding materials 101 and 102 include solder paste, the bonding materials 101 and 102 are cooled so that the bonding materials 101 and 102 are solidified. Then, the third bonding material 103 is applied to a portion of the secondary die pad 70 on which the insulating chip 50 will be mounted. The third bonding material 103 is an insulative bonding material. The insulating substrate 90 is mounted on the third bonding material 103. The fourth bonding material 104 is applied to the insulating substrate 90. The fourth bonding material 104 is an insulative bonding material. The insulating chip 50 is mounted on the fourth bonding material 104. The bonding materials 103 and 104 are solidified. In an example, when the bonding materials 103 and 104 are formed from a material including an epoxy resin, the epoxy resin is mixed with a curing agent so that the bonding materials 103 and 104 are solidified.

In the wire forming step, a wire W that connects each of the chips 30, 40, and 50, wires W that connect the first chip 30 to the primary leads, and wires W that connect the second chip 40 to the secondary leads are formed. The wires W are formed by, for example, a wire bonder.

In the resin layer forming step, a resin layer is formed to encapsulate the chips 30, 40, and 50, the wires W, and the die pads 60 and 70. The resin layer is configured to form the encapsulation resin 80 and is formed from, for example, a black epoxy resin. The resin layer is formed by, for example, transfer molding or compression molding. The primary leads and the secondary leads partially project from the resin layer.

In the separating step, the resin layer is cut, and the primary leads, the secondary leads, the primary die pad 60, and the secondary die pad 70 are detached from the frame. In this step, for example, a dicing blade is used to cut the resin layer and the frame. The primary leads and the secondary leads are cut from the frame so that the primary leads and the secondary leads include portions projecting from the resin layer.

In the terminal forming step, the portions of the primary leads and the secondary leads projecting from the resin layer are bent into a predetermined shape by a bending process. The steps described above manufacture the signal transmission device 10.

### Operation

The operation of the present embodiment will now be described.

The insulation voltage of the capacitor embedded in the element insulation layer depends on the opposing distance between the first electrode plate and the second electrode plate of the capacitor. That is, as the opposing distance between the first electrode plate and the second electrode plate increases, the insulation voltage of the capacitor is improved. It is preferred that the opposing distance between the first electrode plate and the second electrode plate of the capacitor is increased to improve the insulation voltage of the insulating chip.

In a structure in which the first electrode plate and the second electrode plate are opposed to each other in thickness-wise direction of the element insulation layer, when the opposing distance between the first electrode plate and the second electrode plate is increased, the element insulation layer is increased in thickness. When the element insulation layer having the increased thickness is formed on a semiconductor wafer, which forms a substrate, the warpage amount of the semiconductor wafer will be increased. This interferes with the manufacturing of the insulating chip.

In this regard, in the present embodiment, the first electrode plate 53A (53B) and the second electrode plate 54A (54B) of the capacitor 15A (15B) are opposed to each other in the first direction (the x-direction) orthogonal to the thickness-wise direction (z-direction) of the element insulation layer 56. With this structure, even when the opposing distance between the first electrode plate 53A (53B) and the second electrode plate 54A (54B), that is, the distance GX between the first electrode plate 53A (53B) and the second electrode plate 54A (54B) in the x-direction, is increased, the thickness TA of the element insulation layer 56 will not be increased. Thus, without increasing the thickness TA of the element insulation layer 56, the insulation voltage of the insulating chip 50 is improved.

### Advantages

The present embodiment has the following advantages.

(1) The insulating chip 50 includes the substrate 55 mounted on the secondary die pad 70, the element insulation layer 56 arranged on the substrate 55, and the capacitor 15A (15B) including the first electrode plate 53A (53B) and the second electrode plate 54A (54B) embedded in the element insulation layer 56. The first electrode plate 53A (53B) and the second electrode plate 54A (54B) are opposed to each other in the first direction (in the present embodiment, the x-direction) orthogonal to the thickness-wise direction (z-direction) of the element insulation layer 56.

In this structure, the distance GX between the first electrode plate 53A (53B) and the second electrode plate 54A (54B) in the x-direction is independent from the thickness TA of the element insulation layer 56. Even when the distance GX between the first electrode plate 53A (53B) and the second electrode plate 54A (54B) in the x-direction is increased, the thickness TA of the element insulation layer 56 will not be increased. Thus, without increasing the thickness TA of the element insulation layer 56, the insulation voltage of the capacitor 15A (15B) is improved. Accordingly, without increasing the thickness TA of the element insulation layer 56, the insulation voltage of the insulating chip 50 is improved.

In addition, when the first electrode plate 53A (53B) and the second electrode plate 54A (54B) are opposed to each other in a direction orthogonal to the thickness-wise direction (z-direction) of the element insulation layer 56, the distance GX between the first electrode plate 53A (53B) and the second electrode plate 54A (54B) may be readily increased in the x-direction. The insulation voltage necessary for the insulating chip 50 is obtained from only the capacitor 15A (15B). Thus, there is no need for capacitors connected in series to improve the insulation voltage of the insulating chip 50.

(2) The insulating chip 50 includes the first electrode pad 51A (51B) electrically connected to the first electrode plate 53A (53B) and the second electrode pad 52A (52B) electrically connected to the second electrode plate 54A (54B). The electrode pads 51A (51B) and 52A (52B) are arranged on the element insulation layer 56. As viewed in the z-direction, the first electrode pad 51A (51B) is arranged at a position to overlap the first electrode plate 53A (53B). As viewed in the z-direction, the second electrode pad 52A (52B) is arranged at a position to overlap the second electrode plate 54A (54B).

In this structure, the distance between the first electrode plate 53A (53B) and the first electrode pad 51A (51B) is shortened. This decreases inductance between the first electrode plate 53A (53B) and the first electrode pad 51A (51B). Also, the distance between the second electrode plate 54A (54B) and the second electrode pad 52A (52B) is shortened. This decreases inductance between the second electrode plate 54A (54B) and the second electrode pad 52A (52B).

(3) The distance GP between the first electrode pad 51A (51B) and the second electrode pad 52A (52B) in the x-direction is greater than or equal to the distance GX between the first electrode plate 53A (53B) and the second electrode plate 54A (54B) in the x-direction.

With this structure, for example, when a wire bonder forms a wire W bonded to the first electrode pad 51A (51B) and then forms a wire W bonded to the second electrode pad 52A (52B), interference of the wire bonder with the wire W bonded to the first electrode pad 51A (51B) is avoided. The same applies to when the wire bonder forms a wire W bonded to the second electrode pad 52A (52B) and then forms a wire W bonded to the first electrode pad 51A (51B). This facilitates formation of a wire W bonded to the first electrode pad 51A (51B) and a wire W bonded to the second electrode pad 52A (52B).

(4) The distance GX between the first electrode plate 53A (53B) and the second electrode plate 54A (54B) in the x-direction is greater than the thickness TA of the element insulation layer 56.

This structure further improves the insulation voltage of the capacitor 15A (15B) while limiting the thickness TA of the element insulation layer 56.

(5) The length LY of the first electrode plate 53A (53B) in the y-direction is larger than the length LZ of the first electrode plate 53A (53B) in the z-direction. The length of the second electrode plate 54A (54B) in the y-direction is greater than the length of the second electrode plate 54A (54B) in the z-direction.

This structure allows for an increase in the area in which the first electrode plate 53A (53B) is opposed to the second electrode plate 54A (54B) without increasing the length LZ of the first electrode plate 53A (53B) in the z-direction and the length of the second electrode plate 54A (54B) in the z-direction. That is, an increase in the area in which the first electrode plate 53A (53B) is opposed to the second electrode plate 54A (54B) is allowed without increasing the thickness TA of the element insulation layer 56. As a result, the capacitance of the capacitors 15A and 15B is increased.

(6) The signal transmission device 10 includes the first chip 30 including the primary circuit 13, the insulating chip 50, and the second chip 40 including the secondary circuit 14 configured to receive a signal from the primary circuit 13 through the insulating chip 50. The insulating chip 50 includes the substrate 55 mounted on the secondary die pad 70, the element insulation layer 56 arranged on the substrate 55, and the capacitor 15A (15B) including the first electrode plate 53A (53B) and the second electrode plate 54A (54B) embedded in the element insulation layer 56. The first electrode plate 53A (53B) and the second electrode plate 54A (54B) are opposed to each other in the first direction (in the present embodiment, the x-direction) orthogonal to the thickness-wise direction (z-direction) of the element insulation layer 56.

In this structure, the distance GX between the first electrode plate 53A (53B) and the second electrode plate 54A (54B) in the x-direction is independent from the thickness TA of the element insulation layer 56. Even when the distance GX between the first electrode plate 53A (53B) and the second electrode plate 54A (54B) in the x-direction is increased, the thickness TA of the element insulation layer 56 will not be increased. Thus, without increasing the thickness TA of the element insulation layer 56, the insulation voltage of the capacitor 15A (15B) is improved. Accordingly, without increasing the thickness TA of the element insulation layer 56, the insulation voltage of the insulating chip 50 is improved. Thus, the insulation voltage of the signal transmission device 10 is improved.

(7) The insulating chip 50 is mounted on the secondary die pad 70 in a state insulated from the secondary die pad 70.

This structure improves the insulation voltage between the insulating chip 50 and the secondary die pad 70 as compared to a structure in which the insulating chip 50 is mounted on the secondary die pad 70 in a state electrically connected to the secondary die pad 70.

(8) The insulating substrate 90 is arranged between the insulating chip 50 and the secondary die pad 70.

In this structure, the distances D1 and D2 between the first electrode plate 53A (53B) and the secondary die pad 70 and between the second electrode plate 54A (54B) and the secondary die pad 70 in the z-direction are increased. Thus, the insulation voltage between the first electrode plate 53A (53B) and the secondary die pad 70 and between the second electrode plate 54A (54B) and the secondary die pad 70 is improved.

(9) The insulating substrate 90 is bonded to the secondary die pad 70 by the third bonding material 103. The third bonding material 103 includes an insulative bonding material

In this structure, the insulation voltage between the first electrode plate 53A (53B) and the secondary die pad 70 and between the second electrode plate 54A (54B) and the secondary die pad 70 is improved.

(10) The insulating substrate 90 is formed by an insulating substrate including alumina or an insulating substrate including glass.

In this structure, the insulating substrate 90 having a large thickness is readily formed as compared to a structure in which the insulating substrate 90 is formed of an insulation film.

### Modified Examples

The embodiment described above may be modified as follows. The embodiment and the following modified examples can be combined as long as the combined modifications remain technically consistent with each other.

The structure of the substrate 55 may be changed in any manner. In an example, a silicon-on-insulator (SOI) substrate may be used as the substrate 55.

At least one of the protective film 57 and the passivation film 58 may be omitted.

The third bonding material 103 may be formed from a conductive bonding material instead of an insulative bonding material. The fourth bonding material 104 may be formed from a conductive bonding material instead of an insulative bonding material. That is, the insulating chip 50 may be mounted on the secondary die pad 70, or the mount frame, in a state electrically connected to the secondary die pad 70.

The encapsulation resin 80 may be omitted from the signal transmission device 10.

The first electrode plate 53A (53B) and the second electrode plate 54A (54B) of the capacitor 15A (15B) may be opposed to each other in the y-direction.

The distance GX between the first electrode plate 53A (53B) and the second electrode plate 54A (54B) of the capacitor 15A (15B) in the x-direction may be less than or equal to the distance D3 between the first electrode plate 53A (53B) and the substrate 55 in the z-direction. The distance GX between the first electrode plate 53A (53B) and the second electrode plate 54A (54B) of the capacitor 15A (15B) in the x-direction may be less than or equal to the distance D4 between the second electrode plate 54A (54B) and the substrate 55 in the z-direction.

The distance GX between the first electrode plate 53A (53B) and the second electrode plate 54A (54B) of the capacitor 15A (15B) in the x-direction may be less than or equal to the thickness TA of the element insulation layer 56.

The first electrode plate 53A (53B) may be formed integrally with the first electrode pad 51A (51B). In this case, the first electrode plate 53A (53B) and the first electrode pad 51A (51B) are formed from the same material. Also, the second electrode plate 54A (54B) may be formed integrally with the second electrode pad 52A (52B). In this case, the second electrode plate 54A (54B) and the second electrode pad 52A (52B) may be formed from the same material.

The insulating chip 50 may be mounted on the primary die pad 60 instead of the secondary die pad 70. In this case, the first chip 30 and the insulating chip 50 are mounted on the primary die pad 60. The mounting configuration of the insulating chip 50 on the primary die pad 60 is the same as the mounting configuration of the insulating chip 50 on the secondary die pad 70 in the embodiment described above.

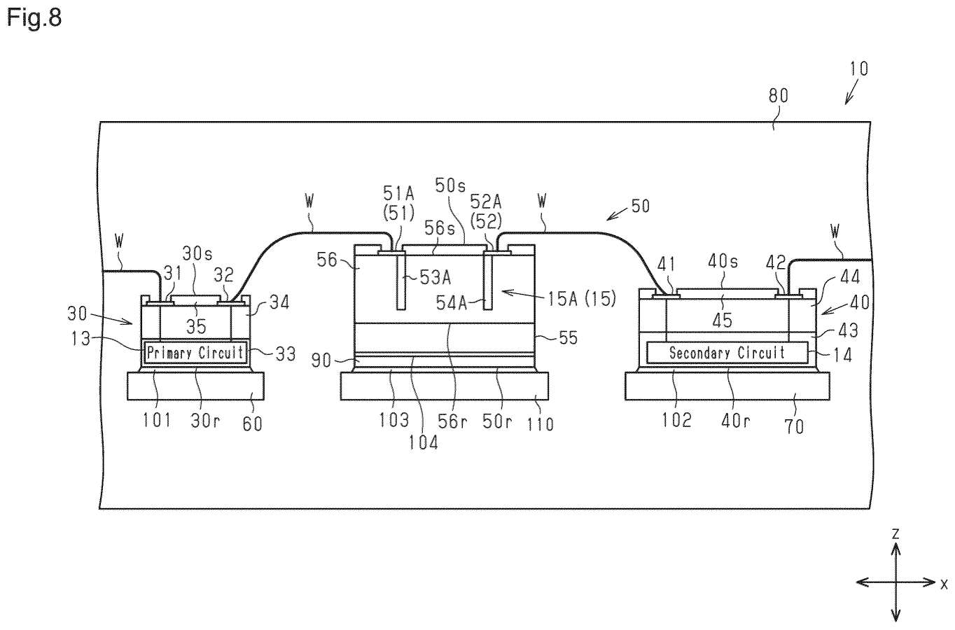

As shown in FIG. 8, the insulating chip 50 may be mounted on an intermediate die pad 110 that differs from the primary die pad 60 and the secondary die pad 70. The intermediate die pad 110 is electrically floating with respect to the primary die pad 60 and the secondary die pad 70. In other words, the insulating chip 50 is mounted on an electrically floating mount frame (intermediate die pad 110). The intermediate die pad 110 corresponds to a “mount frame” and a “third mount frame.”

The intermediate die pad 110 may be, for example, formed simultaneously with the die pads 60 and 70 from the same material as the die pads 60 and 70. The material forming the intermediate die pad 110 may be changed in any manner and may be, for example, formed from a material that differs from that of the die pads 60 and 70. In an example, the intermediate die pad 110 may be formed from ceramics such as alumina or an insulative material such as glass. The intermediate die pad 110 may be formed from a resin material.

In the example shown in FIG. 8, the insulating substrate 90 is bonded to the intermediate die pad 110 by the third bonding material 103. The insulating chip 50 is bonded to the insulating substrate 90 by a fourth bonding material 104.

Since the intermediate die pad 110 is electrically floating, the insulating chip 50 may be electrically connected to the intermediate die pad 110. Hence, the third bonding material 103 and the fourth bonding material 104 may be a conductive bonding material. Instead of arranging the insulating substrate 90 between the intermediate die pad 110 and the insulating chip 50, a semiconductor substrate may be used. The insulating substrate 90 may be omitted. That is, the insulating chip 50 may be bonded to the intermediate die pad 110 by the third bonding material 103. In this case, the third bonding material 103 may be a conductive bonding material or an insulative bonding material.

### Structure of Insulating Chip at Chip Back Surface in Modified Examples

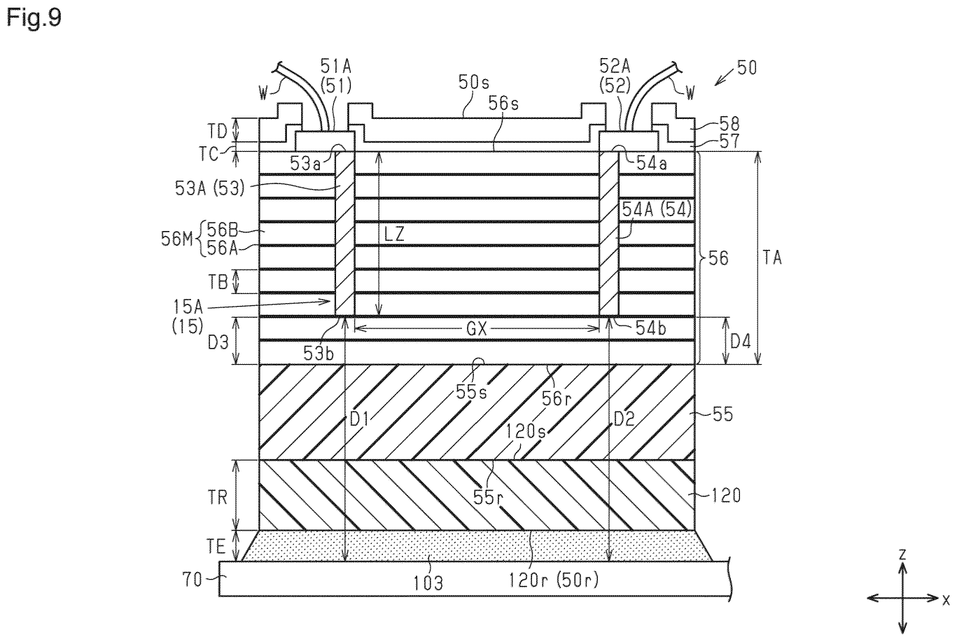

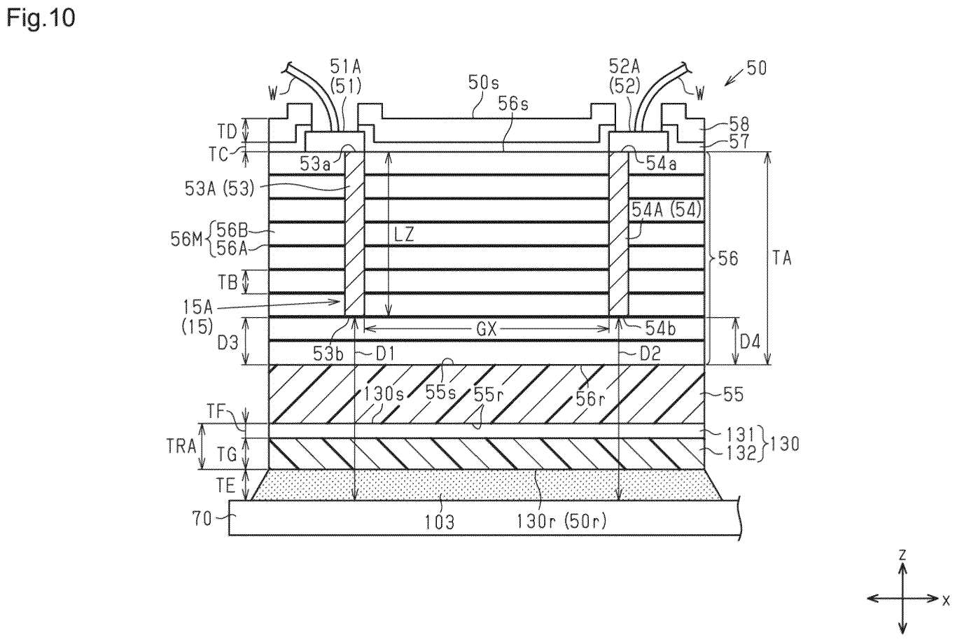

The structure of the insulating chip 50 at the chip back surface 50r may be changed, for example, as in a first example and a second example shown in FIGS. 9 and 10. As shown in FIGS. 9 and 10, the first electrode pads 51A and 51B, the second electrode pads 52A and 52B, the first electrode plates 53A and 53B, the second electrode plates 54A and 54B, the element insulation layer 56, the protective film 57, and the passivation film 58 each have the same structure as those in the embodiment. In the modified examples shown in FIGS. 9 and 10, the insulating substrate 90 and the fourth bonding material 104 (refer to FIG. 4) are not arranged between the insulating chip 50 and the secondary die pad 70. That is, the insulating chip 50 is directly bonded to the secondary die pad 70 by the third bonding material 103.

### First Example of Insulating Chip 50

As shown in FIG. 9, the insulating chip 50 includes a back insulation layer 120 arranged on the substrate back surface 55r of the substrate 55. The back insulation layer 120 is formed from an electrically-insulative material. In an example, the back insulation layer 120 is formed of a layer including, for example, SiO. The back insulation layer 120 is formed by, for example, applying a thermosetting organic siloxane polymer solution having Si—O—Si in the main chain to the substrate back surface 55r. Alternatively, the back insulation layer 120 may be formed of a layer, for example, including resin. Examples of the resin include an epoxy resin, a phenol resin, and a polyimide resin. In the first example, the back insulation layer 120 is formed on the entirety of the substrate back surface 55r. The back insulation layer 120 includes a front surface 120s and a back surface 120r that face opposite directions in the z-direction. The front surface 120s of the back insulation layer 120 is in contact with the substrate back surface 55r. The back surface 120r of the back insulation layer 120 includes the chip back surface 50r of the insulating chip 50.

As shown in FIG. 9, the insulating chip 50 is bonded to the secondary die pad 70 by the third bonding material 103. That is, in the first example, the insulating substrate 90 is not arranged between the insulating chip 50 and the secondary die pad 70. The third bonding material 103 bonds the back surface 120r of the back insulation layer 120 (chip back surface 50r) and the secondary die pad 70. In the same manner as the embodiment described above, the third bonding material 103 includes an insulative bonding material.

The back insulation layer 120 has a thickness TR that is greater than a thickness TB of the insulation films 56M and less than the thickness TA of the element insulation layer 56. The thickness TR of the back insulation layer 120 is less than the length LZ of the first electrode plate 53A in the z-direction. The thickness TR of the back insulation layer 120 is greater than a thickness TC of the protective film 57 and is greater than a thickness TD of the passivation film 58. The thickness TR of the back insulation layer 120 is greater than the distance D3 between the first electrode plate 53A and the substrate 55 in the z-direction. The thickness TR of the back insulation layer 120 is greater than the distance D4 between the second electrode plate 54A and the substrate 55 in the z-direction. The thickness TR of the back insulation layer 120 is greater than a thickness TE of the third bonding material 103. In an example, the thickness TR of the back insulation layer 120 is in a range of 5 μm to 100 μm. The thickness TE of the third bonding material 103 is less than 10 um (approximately a few μm).

The thickness TR of the back insulation layer 120 is defined by the distance between the front surface 120s and the back surface 120r of the back insulation layer 120 in the z-direction. The thickness TB of the insulation films 56M is defined by the distance between the front surface and the back surface of the insulation films 56M in the z-direction. In this modified example, the insulation films 56M include a first insulation film 56A and a second insulation film 56B. The thickness TB of the insulation films 56M is defined by the distance between a back surface of the first insulation film 56A and a front surface of the second insulation film 56B in the insulation films 56M in the z-direction. The thickness TC of the protective film 57 is defined by a distance between a front surface and a back surface of the protective film 57 in the z-direction. The front surface of the protective film 57 is in contact with the passivation film 58. The back surface of the protective film 57 is in contact with the element insulation layer 56. The thickness TD of the passivation film 58 is defined by the distance between a front surface and a back surface of the passivation film 58 in the z-direction. The front surface of the passivation film 58 includes the chip front surface 50s of the insulating chip 50. The back surface of the passivation film 58 is in contact with the protective film 57.

In this structure, the distances D1 and D2 between the secondary die pad 70 and the capacitor 15A in the z-direction are increased as compared to a structure in which an insulating chip does not include the back insulation layer 120 and is bonded to the secondary die pad 70 by the third bonding material 103. This improves the insulation voltage between the insulating chip 50 and the secondary die pad 70, thereby improving the insulation voltage of the signal transmission device 10.

In order to increase the thickness TE of the third bonding material 103, the volume of the third bonding material 103 needs to be increased. However, the third bonding material 103 applied to the secondary die pad 70 spreads when wet. Hence, to increase the thickness TE of the third bonding material 103, the third bonding material 103 may be increased in area as viewed in the z-direction and spread beyond the secondary die pad 70. The wet-spreading of the third bonding material 103 imposes limitations on the increasing of the thickness TE of the third bonding material 103.

In this regard, in the structure of the first example, the back insulation layer 120 is increased in thickness more readily than the third bonding material 103. Therefore, the thickness TR of the back insulation layer 120 is increased more readily than the thickness TE of the third bonding material 103. Thus, the distances D1 and D2 between the capacitor 15A and the secondary die pad 70 in the z-direction are readily increased.

When the back insulation layer 120 includes resin, the thickness TR of the back insulation layer 120 is readily increased as compared to when the back insulation layer 120 is formed of, for example, an oxide film.

The thickness TR of the back insulation layer 120 may be greater than the distance D3 between the first electrode plate 53A and the substrate front surface 55s of the substrate 55 in the z-direction and the distance D4 between the second electrode plate 54A and the substrate front surface 55s in the z-direction. Thus, the distances D1 and D2 between the capacitor 15A and the secondary die pad 70 in the z-direction may be increased without increasing the distances D3 and D4.

The thickness TR of the back insulation layer 120 may be changed in any manner. In an example, the thickness TR of the back insulation layer 120 is greater than the length LZ of the first electrode plate 53A in the z-direction. The thickness TR may be greater than or equal to the thickness TA of the element insulation layer 56. The thickness TR of the back insulation layer 120 may be less than or equal to the thickness TE of the third bonding material 103 and may be less than or equal to the distances D3 and D4.

### Second Example of Insulating Chip 50

As shown in FIG. 10, the insulating chip 50 includes a back insulation layer 130 arranged on the substrate back surface 55r of the substrate 55. The back insulation layer 130 includes an oxide film 131 and an insulation layer 132. The back insulation layer 130 includes a front surface 130s and a back surface 130r that face opposite directions. The front surface 130s is in contact with the substrate back surface 55r. The back surface 130r includes the chip back surface 50r of the insulating chip 50.

The oxide film 131 is arranged on the substrate back surface 55r of the substrate 55. The oxide film 131 is formed from, for example, a material including SiO₂. The oxide film 131 is arranged on the entirety of the substrate back surface 55r.

The insulation layer 132 and the substrate 55 are arranged at opposite sides of the oxide film 131. The insulation layer 132 may be formed by applying a thermosetting organic siloxane polymer solution having Si—O—Si in the main chain to the oxide film 131. Thus, the insulation layer 132 is formed of a layer including SiO. The oxide film 131 includes a front surface and a back surface that face opposite directions. The front surface of the oxide film 131 is in contact with the substrate 55. The insulation layer 132 is formed on the entirety of the back surface of the oxide film 131. Thus, the oxide film 131 is located between the substrate 55 and the insulation layer 132 in the z-direction. The oxide film 131 includes the front surface 130s of the back insulation layer 130. The insulation layer 132 includes the back surface 130r of the back insulation layer 130. In other words, the insulation layer 132 includes the chip back surface 50r of the insulating chip 50.

The insulation layer 132 may be formed from a material including resin. In this case, the insulation layer 132 is a resin layer. The insulation layer 132 (resin layer) may be formed from a material including, for example, one of an epoxy resin, a phenol resin, and a polyimide resin.

The back insulation layer 130 has a thickness TRA, that is, the total thickness of a thickness TF of the oxide film 131 and a thickness TG of the insulation layer 132. The thickness TRA of the back insulation layer 130 is greater than the thickness TE of the third bonding material 103. More specifically, the thickness TG of the insulation layer 132 is greater than the thickness TF of the oxide film 131. The thickness TF of the oxide film 131 is smaller than the thickness TE of the third bonding material 103. The thickness TG of the insulation layer 132 is equal to the thickness TE of the third bonding material 103. Therefore, the total thickness (the thickness TRA of the back insulation layer 130) of the thickness TF of the oxide film 131 and the thickness TG of the insulation layer 132 is greater than the thickness TE of the third bonding material 103.

The thickness TF of the oxide film 131 is defined by the distance between a surface (front surface) of the oxide film 131 that is in contact with the substrate back surface 55r of the substrate 55 and a surface (back surface) of the oxide film 131 that is in contact with the insulation layer 132 in the z-direction. The thickness TG of the insulation layer 132 is defined by the distance in the z-direction between a surface (front surface) of the insulation layer 132 that is in contact with the oxide film 131 and a surface (back surface) of the insulation layer 132 that is opposite to the front surface in the z-direction. The back surface of the insulation layer 132 includes the back surface 130r of the back insulation layer 130 (the chip back surface 50r of the insulating chip 50).

The thickness TRA of the back insulation layer 130 is less than the length LZ of the first electrode plate 53A in the z-direction. The thickness TRA of the back insulation layer 130 is greater than the thickness TC of the protective film 57 and the thickness TD of the passivation film 58. The thickness TRA of the back insulation layer 130 is greater than the thickness TB of the insulation films 56M and less than the thickness TA of the element insulation layer 56. The thickness TRA of the back insulation layer 130 is greater than the distance D3 between the first electrode plate 53A and the substrate 55 in the z-direction. The thickness TRA of the back insulation layer 130 is greater than the distance D4 between the second electrode plate 54A and the substrate 55 in the z-direction.

The thickness TF of the oxide film 131 is less than the distance D3 between the first electrode plate 53A and the substrate 55 in the z-direction. The thickness TF of the oxide film 131 is less than the distance D4 between the second electrode plate 54A and the substrate 55 in the z-direction. The thickness TF of the oxide film 131 may be equal to the thickness TB of the insulation films 56M.

The thickness TG of the insulation layer 132 is greater than the thickness TC of the protective film 57. The thickness TG of the insulation layer 132 is greater than or equal to the thickness TD of the passivation film 58. The thickness TF of the oxide film 131 may be greater than or equal to the thickness TC of the protective film 57. The thickness TF of the oxide film 131 and the thickness TG of the insulation layer 132 may be changed in any manner.

In this structure, the distances D1 and D2 between the secondary die pad 70 and the capacitor 15A in the z-direction are increased as compared to a structure in which an insulating chip does not include the back insulation layer 130 and is bonded to the secondary die pad 70 by the third bonding material 103. This improves the insulation voltage between the insulating chip 50 and the secondary die pad 70, thereby improving the insulation voltage of the signal transmission device 10.

The thickness TG of the insulation layer 132, which is increased in thickness more readily than the oxide film 131, is greater than the thickness TF of the oxide film 131. Thus, the distances D1 and D2 between the secondary die pad 70 and the capacitor 15A are increased the z-direction.

The thickness TF of the oxide film 131, which is not readily increased in thickness, is smaller than the thickness TE of the third bonding material 103. This facilitates formation of the back insulation layer 130 including the oxide film 131 and the insulation layer 132.

In the modified examples of the insulating chip 50 shown in FIGS. 9 and 10, the insulating substrate 90 may be arranged between the insulating chip 50 and the secondary die pad 70. In this case, the structure for mounting the insulating chip 50 on the secondary die pad 70 via the insulating substrate 90 is the same as that in the embodiment.

### Structure of Element Insulation Layer in Modified Example

The structure of the insulation films 56M forming the element insulation layer 56 may be changed in any manner. In an example, as shown in FIGS. 9 and 10, the insulation films 56M each include the first insulation film 56A and the second insulation film 56B formed on the first insulation film 56A.

The first insulation film 56A is, for example, an etch stop film, and is formed from a material including SiN, SiC, silicon carbon nitride (SiCN), or the like. The first insulation film 56A, for example, inhibits diffusion of Cu. That is, the first insulation film 56A is a Cu diffusion barrier film. The first insulation film 56A, for example, restricts warpage. More specifically, the first insulation film 56A is configured to warp in a direction opposite to a warping direction of the second insulation film 56B. In the modified examples shown in FIGS. 9 and 10, the first insulation film 56A is formed from a material including SiN. The second insulation film 56B is, for example, an interlayer insulation film and is an oxide film formed from a material including SiO₂. As shown in FIGS. 9 and 10, the thickness of the second insulation film 56B is greater than the thickness of the first insulation film 56A. The thickness of the first insulation film 56A may be in a range of 50 nm to 1000 nm. The thickness of the second insulation film 56B may be in a range of 500 nm to 5000 nm. In an example, the thickness of the first insulation film 56A is, for example, approximately 300 nm. The thickness of the second insulation film 56B is, for example, approximately 2000 nm.

The insulating chip 50 may include one or more resin layers as the element insulation layer 56 instead of the insulation films 56M. The resin layers may include a material including any one of polyimide resin, phenol resin, and epoxy resin.

### Shape of Capacitor in Modified Examples

The shapes of the electrode plates 53A, 53B, 54A, and 54B in the capacitors 15A and 15B are not limited to being flat and may be changed in any manner. As described below in a first example and a second example of the capacitor 15A, a tubular electrode plate having an axis extending in the z-direction may be used. The same applies to the capacitor 15B.

### Capacitor in First Example

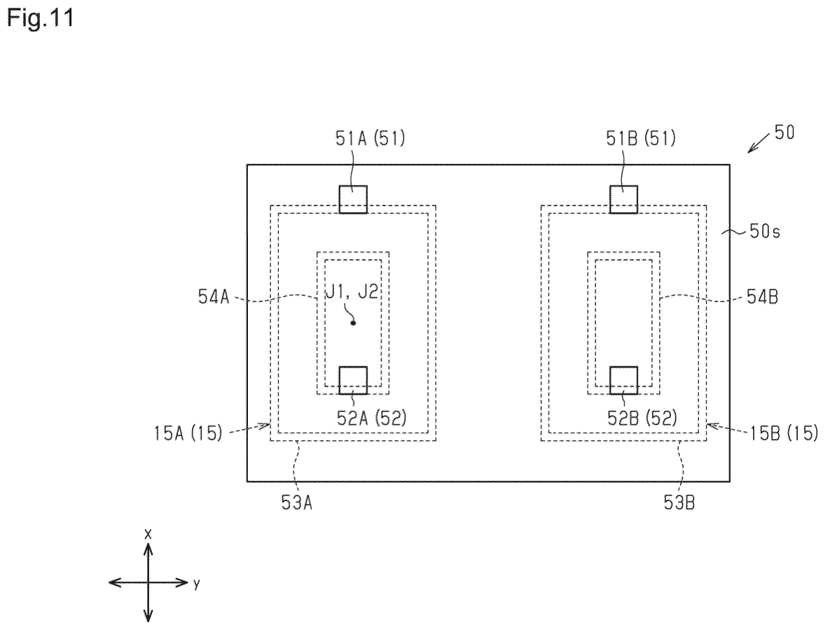

As shown in FIG. 11, as viewed in the z-direction, the first electrode plate 53A and the second electrode plate 54A are each rectangular. That is, the first electrode plate 53A and the second electrode plate 54A each have the shape of a rectangular tube. The first electrode plate 53A is larger than the second electrode plate 54A in dimension in the z-direction.

As viewed in the z-direction, the first electrode plate 53A is formed to surround the second electrode plate 54A. In other words, the second electrode plate 54A is arranged inside the first electrode plate 53A. Thus, in a direction orthogonal to the z-direction, the first electrode plate 53A is opposed to the second electrode plate 54A.

The first electrode plate 53A has an axis J1. The second electrode plate 54A has an axis J2. In the illustrated example, the first electrode plate 53A and the second electrode plate 54A are arranged so that the axis J1 of the first electrode plate 53A coincides with the axis J2 of the second electrode plate 54A. That is, the first electrode plate 53A and the second electrode plate 54A are arranged to be concentric.

As viewed in the z-direction, the first electrode pad 51A is located closer to the first chip 30 (refer to FIG. 2) than the axis J1 of the first electrode plate 53A is. As viewed in the z-direction, the first electrode pad 51A is arranged at a position to overlap the first electrode plate 53A. In the illustrated example, as viewed in the z-direction, the first electrode pad 51A is arranged at a position to overlap one of two ends of the first electrode plate 53A in the x-direction that is located closer to the second chip 40.

As viewed in the z-direction, the second electrode pad 52A is located closer to the second chip 40 (refer to FIG. 2) than the axis J2 of the second electrode plate 54A is. As viewed in the z-direction, the second electrode pad 52A is arranged at a position to overlap the second electrode plate 54A. In the illustrated example, as viewed in the z-direction, the second electrode pad 52A is arranged at a position to overlap one of two ends of the second electrode plate 54A in the x-direction that is located closer to the first chip 30.

As shown in FIG. 11, the structure and arrangement of the first electrode plate 53B, the second electrode plate 54B, the first electrode pad 51B, and the second electrode pad 52B are the same as those of the first electrode plate 53A, the second electrode plate 54A, the first electrode pad 51A, and the second electrode pad 52A.

As viewed in the z-direction, the first electrode plate 53A (53B) may include four corners, each of which is rounded to be curved. The second electrode plate 54A (54B) may include four corners, each of which is rounded and curved. This reduces concentration of an electric field on the corners of the first electrode plate 53A (53B) and the second electrode plate 54A (54B).

### Capacitor in Second Example

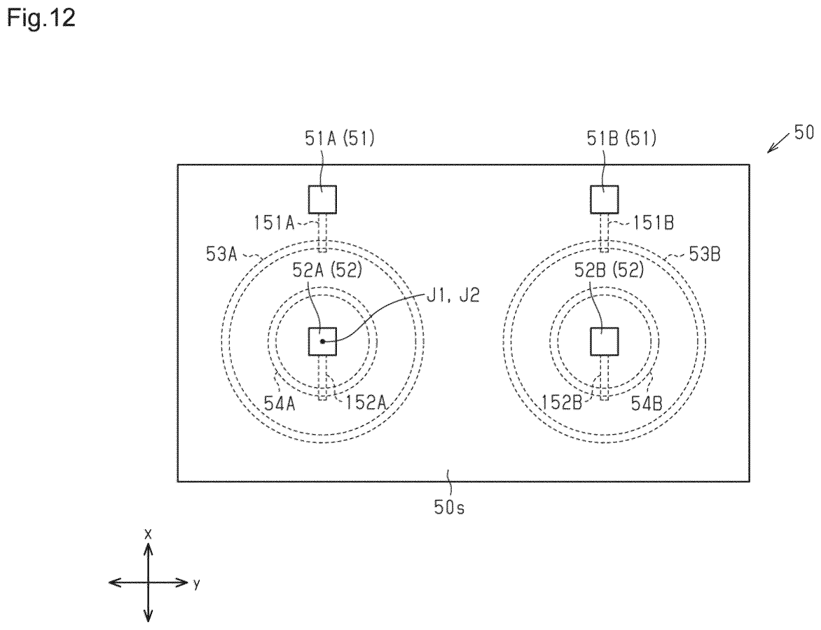

As shown in FIG. 12, as viewed in the z-direction, the first electrode plate 53A and the second electrode plate 54A are each circular. That is, the first electrode plate 53A and the second electrode plate 54A each have the shape of a circular tube. The first electrode plate 53A has a larger outer diameter than the second electrode plate 54A.

As viewed in the z-direction, the first electrode plate 53A is formed to surround the second electrode plate 54A. In other words, the second electrode plate 54A is arranged inside the first electrode plate 53A. Thus, in a direction orthogonal to the z-direction, the first electrode plate 53A is opposed to the second electrode plate 54A.

In the illustrated example, the first electrode plate 53A and the second electrode plate 54A are arranged so that the axis J1 of the first electrode plate 53A coincides with the axis J2 of the second electrode plate 54A. That is, the first electrode plate 53A and the second electrode plate 54A are arranged to be concentric. In other words, the first electrode plate 53A and the second electrode plate 54A are arranged to be coaxial. Thus, as viewed in the z-direction, the distance between the first electrode plate 53A and the second electrode plate 54A is constant along the entire circumference of the first electrode plate 53A.

As viewed in the z-direction, the first electrode pad 51A is located closer to the first chip 30 (refer to FIG. 2) than the first electrode plate 53A is. In other words, as viewed in the z-direction, the first electrode pad 51A is arranged so as not to overlap the first electrode plate 53A. The first electrode pad 51A and the first electrode plate 53A are electrically connected by a first interconnect 151A. The first interconnect 151A is formed on the front surface 56s of the element insulation layer 56 in the same manner as the first electrode pad 51A.

As viewed in the z-direction, the second electrode pad 52A is arranged inside the second electrode plate 54A. In the illustrated example, as viewed in the z-direction, the second electrode pad 52A is arranged not to overlap the second electrode plate 54A. The second electrode pad 52A and the second electrode plate 54A are electrically connected by a second interconnect 152A. The second interconnect 152A is formed on the front surface 56s of the element insulation layer 56 in the same manner as the second electrode pad 52A. The interconnects 151A and 152A are formed from a material including, for example, Al. The interconnects 151A and 152A may be formed from any material and may be formed from a material including, for example, Cu, W, Ti, Ni, Pd, or the like.

As shown in FIG. 12, the structure and arrangement of the first electrode plate 53B, the second electrode plate 54B, the first electrode pad 51B, and the second electrode pad 52B are the same as those of the first electrode plate 53A, the second electrode plate 54A, the first electrode pad 51A, and the second electrode pad 52A. The first electrode pad 51B and the first electrode plate 53B are electrically connected by a first interconnect 151B. The second electrode pad 52B and the second electrode plate 54B are electrically connected by a second interconnect 152B. The material forming the second interconnects 151B and 152B may be, for example, the same as the material forming the interconnects 151A and 152A.

In the capacitors of the first and second examples, the arrangement of the first electrode pad 51A (51B) and the second electrode pad 52A (52B) may be changed in any manner. In an example, in the capacitor of the first example shown in FIG. 11, the first electrode pad 51A (51B) and the second electrode pad 52A (52B) may be arranged so as not to overlap the first electrode plate 53A (53B) and the second electrode plate 54A (54B) as viewed in the z-direction in the same manner as the first electrode pad 51A (51B) and the second electrode pad 52A (52B) in the capacitor of the second example shown in FIG. 12. In an example, in the capacitor of the second example shown in FIG. 12, the first electrode pad 51A (51B) and the second electrode pad 52A (52B) may be arranged at a position to overlap the first electrode plate 53A (53B) and the second electrode plate 54A (54B) as viewed in the z-direction in the same manner as the first electrode pad 51A (51B) and the second electrode pad 52A (52B) in the capacitor of the first example shown in FIG. 11.

Positional Relationship between Electrode Pad and Capacitor in Modified Example

The positional relationship of the electrode pads 51A and 52A with the capacitor 15A and the positional relationship of the electrode pads 51B and 52B with the capacitor 15B as viewed in the z-direction may be changed in any manner. For example, the positional relationship of the electrode pads with the capacitor may be changed as described below in first and second examples.

Positional Relationship between Electrode Pad and Capacitor in First Example

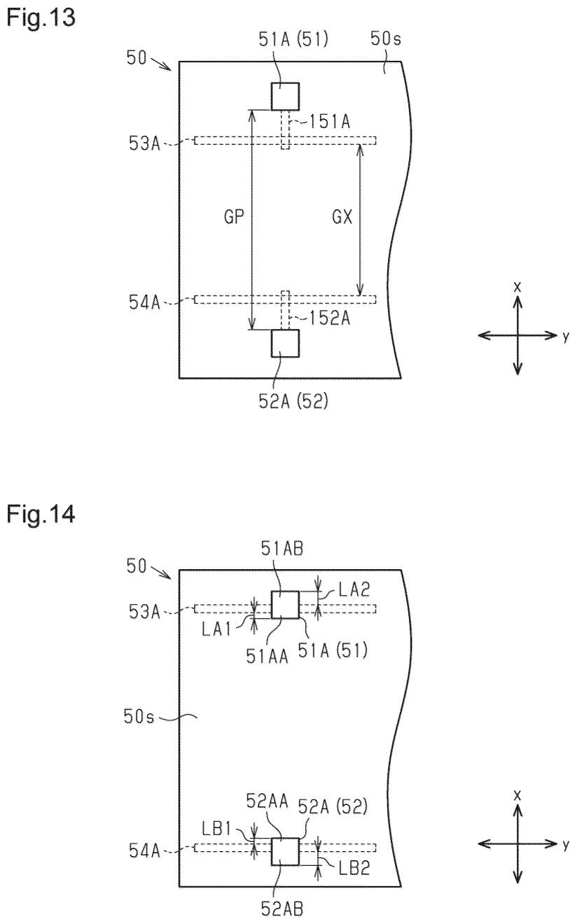

As viewed in the z-direction, the first electrode pad 51A may be arranged so as not to overlap the first electrode plate 53A. As viewed in the z-direction, the second electrode pad 52A may be arranged so as not to overlap the second electrode plate 54A. In an example, as shown in FIG. 13, as viewed in the z-direction, the first electrode pad 51A is located at a side of the first electrode plate 53A opposite from the second electrode plate 54A and separate from the first electrode plate 53A. The first electrode pad 51A and the first electrode plate 53A are connected by the first interconnect 151A. As viewed in the z-direction, the second electrode pad 52A is located at a side of the second electrode plate 54A opposite from the first electrode plate 53A and separate from the second electrode plate 54A. The second electrode pad 52A and the second electrode plate 54A are connected by the second interconnect 152A. In the illustrated example, the distance GP between the first electrode pad 51A and the second electrode pad 52A in the x-direction is greater than the distance GX between the first electrode plate 53A and the second electrode plate 54A in the x-direction. The first electrode pad 51B and the second electrode pad 52B may also be changed in the same manner.

Positional Relationship between Electrode Pad and Capacitor in Second Example

As shown in FIG. 14, as viewed in the z-direction, the first electrode pad 51A extends out from opposite sides of the first electrode plate 53A in the x-direction. More specifically, the first electrode pad 51A includes a first extension 51AA extending from the first electrode plate 53A toward the second electrode plate 54A and a second extension 51AB extending from the first electrode plate 53A away from the second electrode plate 54A. In the illustrated example, a length LA1 of the first extension 51AA in the x-direction may be smaller than a length LA2 of the second extension 51AB in the x-direction.

As viewed in the z-direction, the second electrode pad 52A extends out from opposite sides of the second electrode plate 54A in the x-direction. More specifically, the second electrode pad 52A includes a third extension 52AA extending from the second electrode plate 54A toward the first electrode plate 53A and a fourth extension 52AB extending from the second electrode plate 54A away from the first electrode plate 53A. In the illustrated example, a length LB1 of the third extension 52AA in the x-direction is smaller than a length LB2 of the third extension 52AB in the x-direction.

The length LA1 of the first extension 51AA and the length LA2 of the second extension 51AB may be changed in any manner. The length LA1 may be equal to the length LA2. The length LA1 may be larger than the length LA2. The length LB1 of the third extension 52AA and the length LB2 of the fourth extension 52AB may be changed in any manner. The length LB1 may be equal to the length LB2. The length LB1 may be larger than the length LB2.

### Usage of Insulating Chip in Modified Examples

The insulating chip 50 may be used in a device other than the signal transmission device 10 of the embodiment.

In an example, the insulating chip 50 may be used in a primary circuit module. The primary circuit module includes the first chip 30, the insulating chip 50, and an encapsulation resin that encapsulates the chips 30 and 50. The primary circuit module further includes the primary die pad 60 on which the first chip 30 and the insulating chip 50 are mounted. The first chip 30 is bonded to the primary die pad 60 by the first bonding material 101. The insulating chip 50 is bonded to the primary die pad 60 by the third bonding material 103.

The primary circuit module may include an intermediate die pad arranged separately from the primary die pad 60. The third bonding material 103 and the insulating chip 50 are bonded to the intermediate die pad. The first chip 30 is bonded to the primary die pad 60 by the first bonding material 101.

In another example, the insulating chip 50 may be used in a secondary circuit module. The secondary circuit module includes the second chip 40, the insulating chip 50, and an encapsulation resin that encapsulates the chips 40 and 50. The secondary circuit module further includes the secondary die pad 70 on which the second chip 40 and the insulating chip 50 are mounted. The second chip 40 is bonded to the secondary die pad 70 by the second bonding material 102. The insulating chip 50 is bonded to the secondary die pad 70 by the third bonding material 103.

The secondary circuit module may include an intermediate die pad arranged separately from the secondary die pad 70. The third bonding material 103 and the insulating chip 50 are bonded to the intermediate die pad. The second chip 40 is bonded to the secondary die pad 70 by the second bonding material 102.

### Structure of Signal Transmission Device in Modified Examples

The structure of the signal transmission device 10 may be changed in any manner.

In an example, the signal transmission device 10 may include the primary circuit module and the second chip 40 that are described above. In this case, the second chip 40 may be mounted on the secondary die pad 70, and the secondary die pad 70 and the second chip 40 may be encapsulated by an encapsulation resin to form a module. In this case, the secondary circuit 14 (refer to FIG. 1) included in the second chip 40 corresponds to a “signal transmission circuit.” The second chip 40 corresponds to a “circuit chip.” The signal transmission device 10 corresponds to an “isolation module.”

In another example, the signal transmission device 10 may include the secondary circuit module and the first chip 30. In this case, the first chip 30 may be mounted on the primary die pad 60, and the primary die pad 60 and the first chip 30 may be encapsulated by an encapsulation resin to form a module. In this case, the primary circuit 13 (refer to FIG. 1) included in the first chip 30 corresponds to a “signal transmission circuit.” The first chip 30 corresponds to a “circuit chip.” The signal transmission device 10 corresponds to an “isolation module.”

The transmission direction of a signal in the signal transmission device 10 may be changed in any manner. In an example, the signal transmission device 10 may be configured to transmit a signal from the secondary circuit 14 to the primary circuit 13 through the capacitor 15. More specifically, when the secondary terminals 12 receive a signal (e.g., feedback signal) from the drive circuit, which is electrically connected to the secondary circuit 14 through the secondary terminals 12, the secondary circuit 14 transmits a signal to the primary circuit 13 through the capacitor 15. Then, the signal is output from the primary circuit 13 to the controller, which is electrically connected to the primary circuit 13 through the primary terminals 11. In another example, the signal transmission device 10 may be configured to bidirectionally transmit a signal between the primary circuit 13 and the secondary circuit 14. More specifically, the signal transmission device 10 may include the primary circuit 13 and the secondary circuit 14, which is configured to perform at least one of transmission of a signal and reception of a signal with the primary circuit 13 through the capacitor 15.

In the present disclosure, the term “on” includes the meaning of “above” in addition to the meaning of “on” unless otherwise clearly indicated in the context. Therefore, the phrase “first member formed on second member” is intended to mean that the first member may be formed on the second member in contact with the second member in one embodiment and that the first member may be located above the second member without contacting the second member in another embodiment. In other words, the term “on” does not exclude a structure in which another member is formed between the first member and the second member.

The z-direction as referred to in the present disclosure does not necessarily have to be the vertical direction and does not necessarily have to be fully aligned with the vertical direction. In the structures according to the present disclosure, “upward” and “downward” in the z-direction as referred to in the present description are not limited to “upward” and “downward” in the vertical direction. In an example, the x-direction may be aligned with the vertical direction. In another example, the y-direction may be aligned with the vertical direction.

In the present disclosure, “at least one of A and B” should be understood to mean “only A, only B, or both A and B.”

### CLAUSES

The technical aspects that are understood from the embodiment and the modified examples will be described below. To facilitate understanding without intention to limit, the reference signs of the elements in the embodiments are given to the corresponding elements in the clause with parentheses. The reference signs are used as examples to facilitate understanding, and the components in each clause are not limited to those components given with the reference signs.

### [Clause 1]

An insulating chip (50), including:
a substrate (55);
an element insulation layer (56) arranged on the substrate (55); and
a capacitor (15A, 15B) including a first electrode plate (53A, 53B) and a second electrode plate (54A, 54B) embedded in the element insulation layer (56),
in which the first electrode plate (53A, 53B) and the second electrode plate (54A, 54B) are opposed to each other in a first direction (x-direction) that is a direction orthogonal to a thickness-wise direction (z-direction) of the element insulation layer (56).

### [Clause 2]

The insulating chip according to clause 1, in which the first electrode plate (53A, 53B) and the second electrode plate (54A, 54B) are each flat and have a thickness extending in the first direction (x-direction).

### [Clause 3]

The insulating chip according to clause 1, further including:
a first electrode pad (51A, 51B) arranged on the element insulation layer (56) and electrically connected to the first electrode plate (53A, 53B); and
a second electrode pad (52A, 52B) arranged on the element insulation layer (56) and electrically connected to the second electrode plate (54A, 54B).

### [Clause 4]

The insulating chip according to clause 3, in which
as viewed in the thickness-wise direction (z-direction) of the element insulation layer (56), the first electrode pad (51A, 51B) is arranged at a side of the first electrode plate (53A, 53B) opposite from the second electrode plate (54A, 54B) and separate from the first electrode plate (53A, 53B), and
as viewed in the thickness-wise direction (z-direction) of the element insulation layer (56), the second electrode pad (52A, 52B) is arranged at a side of the second electrode plate (54A, 54B) opposite from the first electrode plate (53A, 53B) and separate from the second electrode plate (54A, 54B).

### [Clause 5]

The insulating chip according to clause 4, in which a distance (GP) between the first electrode pad (51A, 51B) and the second electrode pad (52A, 52B) in the first direction (x-direction) is greater than or equal to a distance (GX) between the first electrode plate (53A, 53B) and the second electrode plate (54A, 54B) in the first direction (x-direction).

### [Clause 6]

The insulating chip according to clause 3, in which
as viewed in the thickness-wise direction (z-direction) of the element insulation layer (56), the first electrode pad (51A, 51B) is arranged at a position to overlap the first electrode plate (53A, 53B), and
as viewed in the thickness-wise direction (z-direction) of the element insulation layer (56), the second electrode pad (52A, 52B) is arranged at a position to overlap the second electrode plate (54A, 54B).

### [Clause 7]

The insulating chip according to clause 6, in which
the first electrode pad (51A, 51B) has two ends in the first direction (x-direction), one of the two ends of the first electrode pad (51A, 51B) located closer to the second electrode plate (54A, 54B) being arranged at a position to overlap the first electrode plate (53A, 53B) as viewed in the thickness-wise direction (z-direction) of the element insulation layer (56), and
the second electrode pad (52A, 52B) has two ends in the first direction (x-direction), one of the two ends of the second electrode pad (52A, 52B) located closer to the first electrode plate (53A, 53B) being arranged at a position to overlap the second electrode plate (54A, 54B) as viewed in the thickness-wise direction (z-direction) of the element insulation layer (56).

### [Clause 8]

The insulating chip according to clause 6, in which
as viewed in the thickness-wise direction (z-direction) of the element insulation layer (56), the first electrode pad (51A, 51B) extends out from opposite sides of the first electrode plate (53A, 53B) in the first direction (x-direction),
as viewed in the thickness-wise direction (z-direction) of the element insulation layer (56), the second electrode pad (52A, 52B) extends out from opposite sides of the second electrode plate (54A, 54B) in the first direction (x-direction),
the first electrode pad (51A, 51B) includes a first extension (51AA) extending from the first electrode plate (53A, 53B) toward the second electrode plate (54A, 54B) and a second extension (51AB) extending from the first electrode plate (53A, 53B) away from the second electrode plate (54A, 54B),
the second electrode pad (52A, 52B) includes a third extension (52AA) extending from the second electrode plate (54A, 54B) toward the first electrode plate (53A, 53B) and a fourth extension (52AB) extending from the second electrode plate (54A, 54B) away from the first electrode plate (53A, 53B),
a length (LA1) of the first extension (51AA) in the first direction (x-direction) is smaller than a length (LA2) of the second extension (51AB) in the first direction (x-direction), and
a length (LB1) of the third extension (52AA) in the first direction (x-direction) is smaller than a length (LB2) of the fourth extension (52AB) in the first direction (x-direction).

### [Clause 9]

The insulation chip according to any one of clauses 1 to 8 in which a distance (GX) between the first electrode plate (53A, 53B) and the second electrode plate (54A, 54B) in the first direction (x-direction) is greater than a thickness (TA) of the element insulation layer (56).

### [Clause 10]

The insulating chip according to any one of clauses 1 to 9, in which the element insulation layer (56) is arranged between the first electrode plate (53A, 53B) and the substrate (55) and between the second electrode plate (54A, 54B) and the substrate (55).

### [Clause 11]

The insulating chip according to clause 10, in which a distance (GX) between the first electrode plate (53A, 53B) and the second electrode plate (54A, 54B) in the first direction (x-direction) is greater than a distance (D3) between the first electrode plate (53A, 53B) and the substrate (55) in the thickness-wise direction (z-direction) of the element insulation layer (56) and is greater than a distance (D4) between the second electrode plate (54A, 54B) and the substrate (55) in the thickness-wise direction (z-direction) of the element insulation layer (56).

### [Clause 12]

The insulating chip according to clause 1, in which
the first electrode plate (53A, 53B) and the second electrode plate (54A, 54B) are each tubular and have an axis (J1, J2) extending in the thickness-wise direction (z-direction) of the element insulation layer (56), the axis (J1) of the first electrode plate (53A, 53B) coinciding with the axis (J2) of the second electrode plate (54A, 54B),
a dimension of the first electrode plate (53A, 53B) in a direction orthogonal to the thickness-wise direction (z-direction) of the element insulation layer (56) is larger than a dimension of the second electrode plate (54A, 54B) in the direction orthogonal to the thickness-wise direction (z-direction) of the element insulation layer (56), and
the second electrode plate (54A, 54B) is arranged inside the first electrode plate (53A, 53B) and opposed to the first electrode plate (53A, 53B) in the direction orthogonal to the thickness-wise direction (z-direction) of the element insulation layer (56).

### [Clause 13]

The insulating chip according to clause 12, in which the first electrode plate (53A, 53B) and the second electrode plate (54A, 54B) are each circularly tubular.

### [Clause 14]

The insulation chip according to any one of clauses 1 to 13, in which the first electrode plate (53A, 53B) and the second electrode plate (54A, 54B) are formed from a material including at least one of copper, aluminum, and tungsten.

### [Clause 15]

The insulating chip according to any one of clauses 3 to 8, in which the first electrode pad (51A, 51B) and the second electrode pad (52A, 52B) are formed from a material including aluminum.

### [Clause 16]

The insulating chip according to any one of clauses 1 to 15, in which the insulating chip (50) is mounted on a mount frame (70) in a state insulated from the mount frame (70) or the insulating chip (50) is mounted on a mount frame (110) that is electrically floating.

### [Clause 17]

A signal transmission device (10), including:
a first chip (30) including a first circuit (13);
an insulating chip (50); and
a second chip (40) including a second circuit (14) configured to perform at least one of reception of a signal and transmission of a signal with the first circuit (13) through the insulation chip (50), in which
the insulating chip (50) includes
   a substrate (55),
   an element insulation layer (56) arranged on the substrate (55), and
   a capacitor (15A, 15B) including a first electrode plate (53A, 53B) and a second electrode plate (54A, 54B) embedded in the element insulation layer (56), and
the first electrode plate (53A, 53B) and the second electrode plate (54A, 54B) are opposed to each other in a first direction (x-direction) that is a direction orthogonal to a thickness-wise direction (z-direction) of the element insulation layer (56).

### [Clause 18]

The signal transmission device according to clause 17, further including:
a first mount frame (60) on which the first chip (30) is mounted; and
a second mount frame (70) on which the second chip (40) is mounted,
in which the insulation chip (50) is mounted on the first mount frame (60) or the second mount frame (70) via an insulation member (90).

### [Clause 19]

The signal transmission device according to clause 17, further including:
a first mount frame (60) on which the first chip (30) is mounted;
a second mount frame (70) on which the second chip (40) is mounted; and
a third mount frame (110) on which the insulation chip (50) is mounted,
in which the third mount frame (110) is electrically floating with respect to both the first mount frame (60) and the second mount frame (70).

### [Clause 20]

The signal transmission device according to any one of clauses 17 to 19, in which
the signal transmission device (10) is configured to transmit a signal from the first circuit (13) toward the second circuit (14) through the capacitor (15),
the capacitor (15) includes a first signal capacitor (15A) and a second signal capacitor (15B),
the signal transmitted through the capacitor (15) includes a first signal and a second signal,
the first signal is transmitted from the first circuit (13) toward the second circuit (14) through the first signal capacitor (15A), and
the second signal is transmitted from the first circuit (13) toward the second circuit (14) through the second signal capacitor (15B).

### [Clause 21]

The insulating chip according to clause 16, in which an insulation substrate (90) is arranged separately from the insulating chip (50) between the mount frame (70) and the insulating chip (50).

### [Clause 22]

The insulating chip according to clause 21, in which
the insulation substrate (90) is bonded to the mount frame (70) by a first insulative bonding material (103), and
the insulating chip (50) is bonded to the insulation substrate (90) by a second insulative bonding material (104).

### [Clause 23]

The insulating chip according to clause 16, in which
the substrate (55) includes a substrate back surface (55r) facing the mount frame (70) and a substrate front surface (55s) opposite to the substrate back surface (55r), and
a back insulation layer (120,130, 140) is arranged on the substrate back surface (55r).

### [Clause 24]

The insulating chip according to clause 23, in which the back insulation layer (120, 130) includes a resin.

### [Clause 25]

The insulating chip according to clause 23, in which the back insulation layer (130) includes an oxide film (131) arranged on the substrate back surface (55r) and an insulation layer (132) arranged on a side of the oxide film (131) opposite from the substrate (55).

### [Clause 26]

The insulating chip according to clause 25, in which a thickness (TG) of the insulation layer (132) is greater than a thickness (TF) of the oxide film (131).

### [Clause 27]

An isolation module, including:
the insulation chip (50) according to any one of clauses 1 to 16 and 21 to 26; and
a circuit chip (30/40) including a signal transmission circuit (13/14) electrically connected to the insulation chip (50).

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

### REFERENCE SIGNS LIST

10) signal transmission device
10A) signal transmission circuit
11) primary terminal
12) secondary terminal
13) primary circuit
14) secondary circuit
15, 15A, 15B) capacitor
16A, 16B) primary signal line
17A, 17B) secondary signal line
21A, 21B) first electrode
22A, 22B) second electrode
30) first chip
30s) chip front surface
30r) chip back surface
31) first electrode pad
32) second electrode pad
33) first substrate
34) interconnect layer
35) protective film
40) second chip
40s) chip front substrate
40r) chip back surface
41) first electrode pad
42) second electrode pad
43) second substrate
44) interconnect layer
45) protective film
50) insulating chip
50s) insulating chip front surface
50r) insulating chip back surface
51, 51A, 51B) first electrode pad
51AA) first extension
51AB) second extension
52, 52A, 52B) second electrode pad
52AA) third extension
52AB) fourth extension
53A, 53B) first electrode plate
54A, 54B) second electrode plate
53a, 54a) electrode upper surface
53b, 54b) electrode lower surface
55) substrate
55s) substrate front surface
55r) substrate back surface
56) element insulation layer
56s) front surface
56r) back surface
56M) insulation film
56A) first insulation film
56B) second insulation film
57) protective film
58) passivation film
60) primary die pad
70) secondary die pad
80) encapsulation resin
90) insulating substrate
90s) front surface
90r) back surface
101) first bonding material
102) second bonding material
103) third bonding material
104) fourth bonding material
110) intermediate die pad
120) back insulation layer
120s) front surface
120r) back surface
130) back insulation layer
130s) front surface
130r) back surface
131) oxide film
132) insulation layer
151A, 151B) first interconnect
152A, 152B) second interconnect
W) wire
J1, J2) axis
D1) distance between first electrode plate and secondary die pad
D2) distance between second electrode plate and secondary die pad
D3) distance between first electrode plate and substrate of insulating chip
D4) distance between second electrode plate and substrate of insulating chip
GX) opposing distance between first electrode plate and second electrode plate
GP) distance between first electrode pad and second electrode pad
LY) length of first electrode plate in y-direction
LZ) length of first electrode plate in z-direction
LA1) length of first extension
LA2) length of second extension
LB1) length of third extension
LB2) length of fourth extension
TA) thickness of element insulation layer
TB) thickness of insulation film
TC) thickness of protective film
TD) thickness of passivation film
TE) thickness of third bonding material
TF) thickness of oxide film
TG) thickness of insulation layer
TR, TRA) thickness of back insulation layer
TS) thickness of insulating substrate

1. An insulating chip, comprising:
a substrate;
an element insulation layer arranged on the substrate; and
a capacitor including a first electrode plate and a second electrode plate embedded in the element insulation layer,
wherein the first electrode plate and the second electrode plate are opposed to each other in a first direction that is a direction orthogonal to a thickness-wise direction of the element insulation layer.

2. The insulating chip according to claim 1, wherein the first electrode plate and the second electrode plate are each flat and have a thickness extending in the first direction.

3. The insulating chip according to claim 1, further comprising:
a first electrode pad arranged on the element insulation layer and electrically connected to the first electrode plate; and
a second electrode pad arranged on the element insulation layer and electrically connected to the second electrode plate.

4. The insulating chip according to claim 3, wherein
as viewed in the thickness-wise direction of the element insulation layer, the first electrode pad is arranged at a side of the first electrode plate opposite from the second electrode plate and separate from the first electrode plate, and
as viewed in the thickness-wise direction of the element insulation layer, the second electrode pad is arranged at a side of the second electrode plate opposite from the first electrode plate and separate from the second electrode plate.

5. The insulating chip according to claim 3, wherein a distance between the first electrode pad and the second electrode pad in the first direction is greater than or equal to a distance between the first electrode plate and the second electrode plate in the first direction.

6. The insulating chip according to claim 3, wherein
as viewed in the thickness-wise direction of the element insulation layer, the first electrode pad is arranged at a position to overlap the first electrode plate, and as viewed in the thickness-wise direction of the element insulation layer, the second electrode pad is arranged at a position to overlap the second electrode plate.

7. The insulating chip according to claim 6, wherein
the first electrode pad has two ends in the first direction, one of the two ends of the first electrode pad located closer to the second electrode plate being arranged at a position to overlap the first electrode plate as viewed in the thickness-wise direction of the element insulation layer, and
the second electrode pad has two ends in the first direction, one of the two ends of the second electrode pad located closer to the first electrode plate being arranged at a position to overlap the second electrode plate as viewed in the thickness-wise direction of the element insulation layer.

8. The insulating chip according to claim 6, wherein
as viewed in the thickness-wise direction of the element insulation layer, the first electrode pad extends out from opposite sides of the first electrode plate in the first direction,
as viewed in the thickness-wise direction of the element insulation layer, the second electrode pad extends out from opposite sides of the second electrode plate in the first direction,
the first electrode pad includes a first extension extending from the first electrode plate toward the second electrode plate and a second extension extending from the first electrode plate away from the second electrode plate,
the second electrode pad includes a third extension extending from the second electrode plate toward the first electrode plate and a fourth extension extending from the second electrode plate away from the first electrode plate,
a dimension of the first extension in the first direction is smaller than a dimension of the second extension in the first direction, and
a dimension of the third extension in the first direction is smaller than a dimension of the fourth extension in the first direction.

9. The insulation chip according to claim 1, wherein a distance between the first electrode plate and the second electrode plate in the first direction is greater than a thickness of the element insulation layer.

10. The insulating chip according to claim 1, wherein the element insulation layer is arranged between the first electrode plate and the substrate and between the second electrode plate and the substrate.

11. The insulating chip according to claim 10, wherein a distance between the first electrode plate and the second electrode plate in the first direction is greater than a distance between the first electrode plate and the substrate in the thickness-wise direction of the element insulation layer and is greater than a distance between the second electrode plate and the substrate in the thickness-wise direction of the element insulation layer.

12. The insulating chip according to claim 1, wherein
the first electrode plate and the second electrode plate are each tubular and have an axis extending in the thickness-wise direction of the element insulation layer, the axis of the first electrode plate coinciding with the axis of the second electrode plate,
a dimension of the first electrode plate in a direction orthogonal to the thickness-wise direction of the element insulation layer is larger than a dimension of the second electrode plate in the direction orthogonal to the thickness-wise direction of the element insulation layer, and
the second electrode plate is arranged inside the first electrode plate and opposed to the first electrode plate in the direction orthogonal to the thickness-wise direction of the element insulation layer.

13. The insulating chip according to claim 12, wherein the first electrode plate and the second electrode plate are each circularly tubular.

14. The insulation chip according to claim 1, wherein the first electrode plate and the second electrode plate are formed from a material including at least one of copper, aluminum, and tungsten.

15. The insulating chip according to claim 3, wherein the first electrode pad and the second electrode pad are formed from a material including aluminum.

16. The insulating chip according to claim 1, wherein the insulating chip is mounted on a mount frame in a state insulated from the mount frame or the insulating chip is mounted on a mount frame that is electrically floating.

17. A signal transmission device, comprising:
a first chip including a first circuit;
an insulating chip; and
a second chip including a second circuit configured to perform at least one of reception of a signal and transmission of a signal with the first circuit through the insulation chip, wherein
the insulating chip includes
a substrate,
an element insulation layer arranged on the substrate, and
a capacitor including a first electrode plate and a second electrode plate embedded in the element insulation layer, and
the first electrode plate and the second electrode plate are opposed to each other in a first direction that is a direction orthogonal to a thickness-wise direction of the element insulation layer.

18. The signal transmission device according to claim 17, further comprising:
a first mount frame on which the first chip is mounted; and
a second mount frame on which the second chip is mounted,
wherein the insulation chip is mounted on the first mount frame or the second mount frame via an insulation member.

19. The signal transmission device according to claim 17, further comprising:
a first mount frame on which the first chip is mounted;
a second mount frame on which the second chip is mounted; and
a third mount frame on which the insulation chip is mounted,
wherein the third mount frame is electrically floating with respect to both the first mount frame and the second mount frame.

20. The signal transmission device according to claim 17, wherein
the signal transmission device is configured to transmit a signal from the first circuit toward the second circuit through the capacitor,
the capacitor includes a first signal capacitor and a second signal capacitor, the signal transmitted through the capacitor includes a first signal and a second signal,
the first signal is transmitted from the first circuit toward the second circuit through the first signal capacitor, and
the second signal is transmitted from the first circuit toward the second circuit through the second signal capacitor.
